(19) United States
(12) Patent Application Publication
(10) Pub. No.: US 2006/0006504 A1
(43) Pub. Date: Jan. 12, 2006

(54) Multilayer leadframe module with embedded passive component and method of fabricating the same

(76) Inventors: Chien-Chen Lee, Zhubei City (TW); Chao-Hui Lin, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/964,542

(22) Filed: Oct. 13, 2004

(30) Foreign Application Priority Data
Jun. 30, 2004 (TW) 93119890

(51) Int. Cl. H01L 23/495

(52) U.S. Cl. 257/666

(57) ABSTRACT

A multilayer leadframe module with embedded passive components and method of fabricating the same. The leadframe, comprising opposite first and second surfaces, includes an active device base exposed on the first and second surfaces, a trace line, exposed on the first surface, beyond the active device base, a contact pad, exposed at least on the second surface, beyond the trace line, a wiring layer, comprising a passive device, between the first and second surfaces and electrically connecting the trace line and contact pad, and an insulating material among the active device, trace line, contact pad, and the wiring layer, and completely covering the wiring layer.

### BACKGROUND

The invention relates to a package structure and in particular to multilayer leadframe with an embedded passive component.

Due to the demand for high-frequency, high-speed system-in-package (SIP), a small-aspect package design capable of effective heat dissipation and excellent electrical performance is necessary. Thus, package technology is a critical issue in SIP design. QFN (quad flat no-lead), capable of low pin inductance, is a widely anticipated technology, which utilizes a lead frame as a substrate.

A lead frame for QFN has a die paddle, attaching a chip thereto, and a plurality of leads beyond the die paddle. The chip has a plurality of terminals respectively electrically connecting the corresponding leads. An encapsulant covers the chip and respectively exposes the ends of the leads. The lead ends and the encapsulant are approximately coplanar, achieving a QFN package.

A QFN package has smaller aspect and better electrical performance than other package types. In a printed circuit board assembly (PBCA) process, QFN packages and passive devices are individually disposed on a PCB, resulting in the necessity to design PCB wirings to electrically connect corresponding QFN packages and passive devices. The required wirings may enlarge the PCB and/or wiring density thereof, which may cause crosstalk therebetween.

### SUMMARY

Thus, embodiments of the invention provide a multilayer leadframe module with an embedded passive component and method of fabricating the same, thereby reducing the overall size of an end product using the module, and improving the electrical performance thereof.

Embodiments of the invention provide a multilayer leadframe module with an embedded passive component which comprises opposite first and second surfaces, comprising a base, trace line, wiring, and insulating material. The base is exposed in the first and second surfaces. The trace line is disposed beyond the base, and exposed in at least the second surface. The pad is disposed beyond the trace line, and exposed in at least the second surface. The wiring is disposed between the first and second surfaces. The wiring comprises a passive component and respectively electrically connects the trace line and pad. The insulating material is disposed among the base, trace line, pad, and wiring, and substantially covers the wiring.

Embodiments of the invention further provide a multilayer leadframe module with an embedded passive component which comprises opposite first and second surfaces, comprising a base, trace line, first pad, wiring, dielectric material, and insulating material. The base is exposed in the first and second surfaces. The trace line is disposed beyond the base and exposed in the first surface. The first pad is disposed beyond the trace line and exposed in the first and second surfaces. The wiring is disposed underlying the trace line, and electrically connects the first pad. The dielectric material is disposed between at least parts of the trace line and at least parts of the wiring, thereby forming an embedded capacitor comprising the trace line, dielectric material, and wiring. The insulating material is disposed between the base and trace line, and between the trace line and first pad, and extending to the second surface to substantially cover the wiring.

Embodiments of the invention further provide a method for fabricating a leadframe module with an embedded passive component. First, a conductive substrate comprising a top surface and bottom surface is provided. Then, a base embryo and pad embryo beyond the base embryo are formed overlying parts of the top surface of the conductive substrate. Next, a first insulating material is formed overlying the top surface of the conductive substrate beyond the base embryo and pad embryo. Next, the base embryo and pad embryo are thickened, and a wiring, electrically connecting the pad embryo, is formed beyond the base embryo. The wiring comprises a passive component. Next, a second insulating material is formed overlying the first insulating material beyond the base embryo, pad embryo, and wiring. Next, the base embryo and pad embryo are thickened, and an electrical connection layer is formed overlying at least parts of the wiring. Next, a third insulating material is formed to cover the second insulating material and wiring. Next, the base embryo and pad embryo are thickened to serve as the base and pad respectively, and a trace line is formed overlying the electrical connection layer. The trace line is disposed beyond the base, and the pad is disposed beyond the trace line. Further, a fourth insulating material is formed overlying the third insulating material and electrical connection layer beyond the base, pad, and trace line. Finally, the conductive substrate at least underlying the first insulating material is removed.

Embodiments of the invention further provide a method for fabricating a leadframe module with an embedded passive component. First, a conductive substrate comprising a top surface and bottom surface is provided. Then, a base embryo, electrical connection layer beyond the base embryo, and pad embryo beyond the electrical connection layer are formed overlying the top surface of the conductive substrate. Next, a first insulating material is formed overlying the top surface of the conductive substrate beyond the base embryo, electrical connection layer, and pad embryo. Next, the base embryo and pad embryo are thickened, and a wiring, electrically connecting the respective pad embryo and electrical connection layer, is formed beyond the base embryo. The wiring comprises a passive component. Next, a second insulating material is formed overlying the first insulating material beyond the base embryo, pad embryo, and wiring. Next, the base embryo and pad embryo are thickened. Next, a third insulating material is formed overlying the wiring and second insulating material beyond the base embryo and pad embryo. Further, parts of the conductive substrate are removed, resulting in combination of the base embryo and its underlying conductive substrate serving as a base, formation of a trace line electrically connects the wiring through the electrical connection layer, and combination of the pad embryo and its underlying conductive substrate serving as a pad. The trace line is disposed beyond the base, and the pad is disposed beyond the trace line. Finally, a fourth insulating material is formed in positions left by the removed conductive substrate.

Embodiments of the invention further provide a method for fabricating a leadframe module with an embedded passive component. First, a conductive substrate comprising a top surface and bottom surface is provided. A base embryo and pad embryo beyond the base embryo are then formed overlying parts of the top surface of the conductive substrate. Next, a first insulating material is formed overlying the top surface of the conductive substrate beyond the base embryo and pad embryo. Next, the base embryo and pad embryo are thickened, and a wiring, electrically connecting the pad embryo, is formed beyond the base embryo. Next, a second insulating material is formed overlying the first insulating material beyond the base embryo, pad embryo, and wiring. Next, the base embryo and pad embryo are thickened. Next, a dielectric material is formed at least overlying the wiring. Next, the base embryo and pad embryo are thickened to serve as base and pad respectively, and a trace line is formed overlying at least parts of the dielectric material. The trace line is disposed beyond the base, and the pad is disposed beyond the trace line. An embedded capacitor comprising at least parts of the dielectric material disposed between at least parts of the trace line and at least parts of the wiring is formed. Further, a third insulating material is formed overlying the dielectric material beyond the base, pad, and trace line. Finally, the conductive substrate at least underlying the first insulating material is removed.

Embodiments of the invention further provide a method for fabricating a leadframe module with an embedded passive component. First, a conductive substrate comprising a top surface and bottom surface is provided. Then, a base embryo and pad embryo beyond the base embryo are formed overlying the top surface of the conductive substrate. Next, a dielectric material is formed overlying the top surface of the conductive substrate beyond the base embryo and pad embryo. Next, the base embryo and pad embryo are thickened, and a wiring, electrically connecting the pad embryo, is formed beyond the base embryo. Next, a first insulating material is formed overlying the dielectric material beyond the base embryo, pad embryo, and wiring. Next, the base embryo and pad embryo are thickened. Next, a second insulating material is formed overlying the wiring and second insulating material beyond the base embryo and pad embryo. Further, parts of the conductive substrate are removed, resulting in combination of the base embryo and its underlying conductive substrate being a base, formation of a trace line, and combination of the pad embryo and its underlying conductive substrate being a pad. The trace line is disposed beyond the base, and the pad is disposed beyond the trace line. An embedded capacitor, comprising at least parts of the dielectric material disposed between at least parts of the trace line and at least parts of the wiring, is formed. Finally, a third insulating material is formed in positions left by the removed conductive substrate.

Embodiments of the invention further provide a leadframe module with an embedded passive component which comprises opposite first and second surfaces, comprising a base, first and second pads, a wiring, and an insulating material. The base is exposed in the first and second surfaces. The first pad is disposed beyond the base and exposed in the first surface. The second pad is disposed beyond the base and exposed in the second surface. The wiring is disposed between the first and second surfaces. The wiring comprises a passive component and respectively electrically connects the first and second pads. The insulating material is disposed among the base, first surface, second surface, and wiring, and substantially covers the wiring.

Embodiments of the invention further provide a leadframe module with an embedded passive component which comprises opposite first and second surfaces, comprising a base, first and second pads, a wiring, a dielectric material, and an insulating material. The base is exposed in the first and second surfaces. The first pad is disposed beyond the base and exposed in the first surface. The second pad is disposed beyond the base and exposed in the second surface. The wiring is disposed underlying the first pad, and electrically connects the second pad. The dielectric material is disposed between at least parts of the wiring and parts of the first pad to form an embedded capacitor comprised thereof. The insulating material is disposed among the base, first pad, second pad, and dielectric material, and substantially covers the wiring.

Embodiments of the invention further provide a leadframe module with an embedded passive component, comprising a base, two connectors, and an insulating material. The connectors are respectively disposed in two opposite surfaces of the leadframe. The insulating material is disposed between the base and connectors.

### BRIEF DESCRIPTION OF THE DRAWINGS

The invention can be more fully understood by reading the subsequent detailed description in conjunction with the examples and references made to the accompanying drawings, wherein:

FIG. 1U is a cross-section of a leadframe module of a first embodiment of the invention.

FIG. 1V is a cross-section of a leadframe module of a second embodiment of the invention.

FIGS. 1A through 1N and 1P through T are cross-sections of a method for fabricating a leadframe module of a third embodiment of the invention.

FIGS. 2A through 3E are cross-sections of a method for fabricating a leadframe module of a fourth embodiment of the invention.

FIGS. 3A through 3N and 3P through 3T are cross-sections of a method for fabricating a leadframe module of a fifth embodiment of the invention.

FIG. 4M is a cross-section of a leadframe module of a sixth embodiment of the invention.

FIGS. 4A through 4L are cross-sections of a method for fabricating a leadframe module of a seventh embodiment of the invention.

FIGS. 5A through 5N and 5P are cross-sections of a method for fabricating a leadframe module of an eighth embodiment of the invention.

FIG. 6 is a cross-section of a leadframe module of a ninth embodiment of the invention.

FIG. 7 is a cross-section of a leadframe module of a tenth embodiment of the invention.

FIG. 8 is a cross-section of a leadframe module of an eleventh embodiment of the invention.

FIG. 9 is a cross-section of a leadframe module of a twelfth embodiment of the invention.

FIG. 10 is a cross-section of a leadframe module of a thirteenth embodiment of the invention.

FIG. 11 is a three-dimensional skeleton diagram of an example of an embedded resistor of an embodiment of the invention.

FIGS. 12A through 12C are three-dimensional skeleton diagrams of examples of an embedded inductor of an embodiment of the invention.

### DETAILED DESCRIPTION

The following embodiments are intended to illustrate the invention more fully without limiting the scope of the claims, since numerous modifications and variations will be apparent to those skilled in this art.

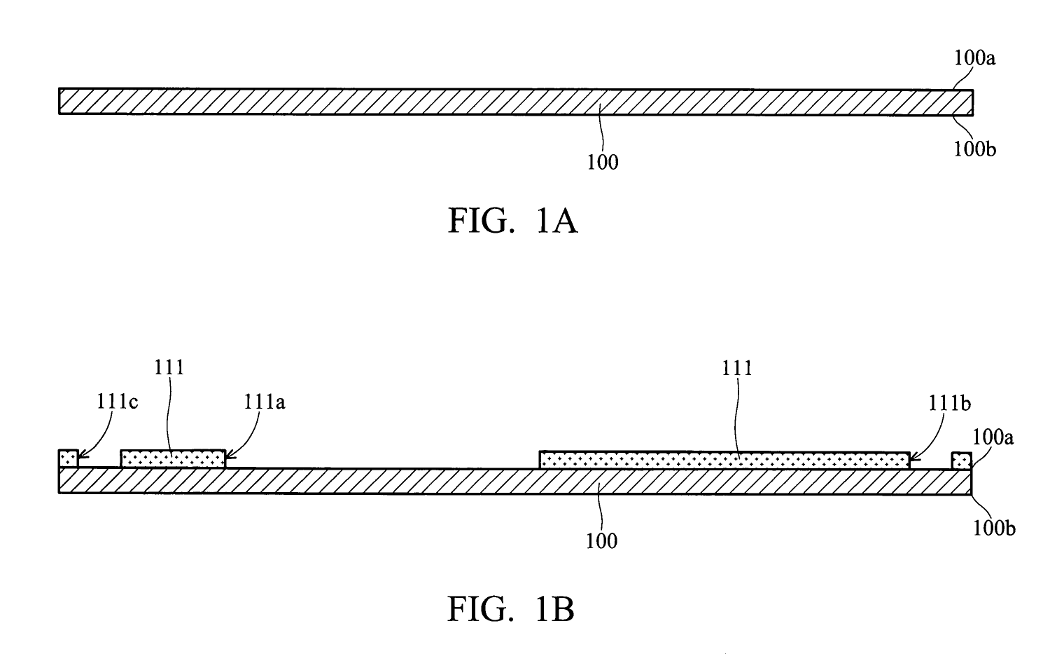

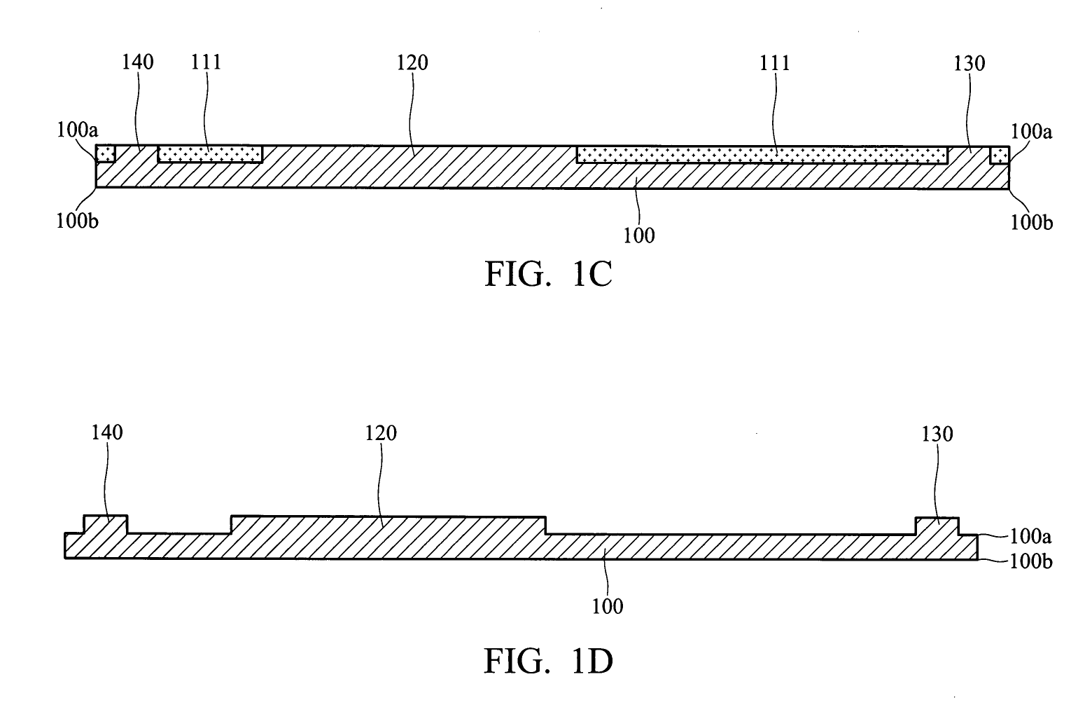

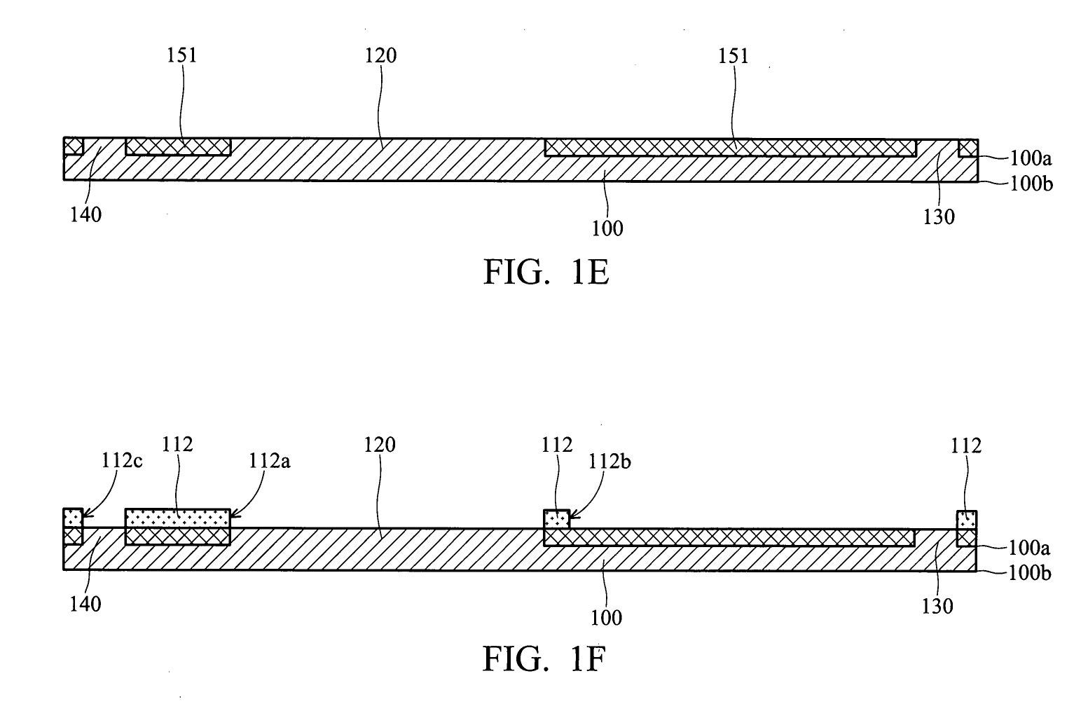

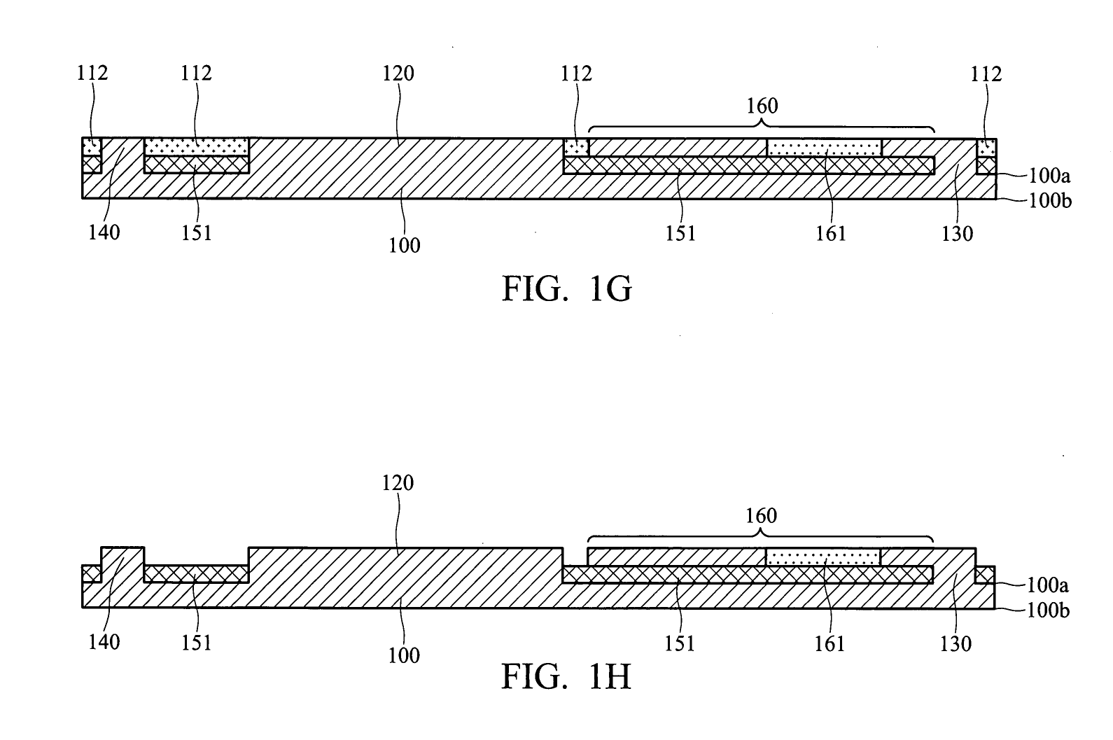

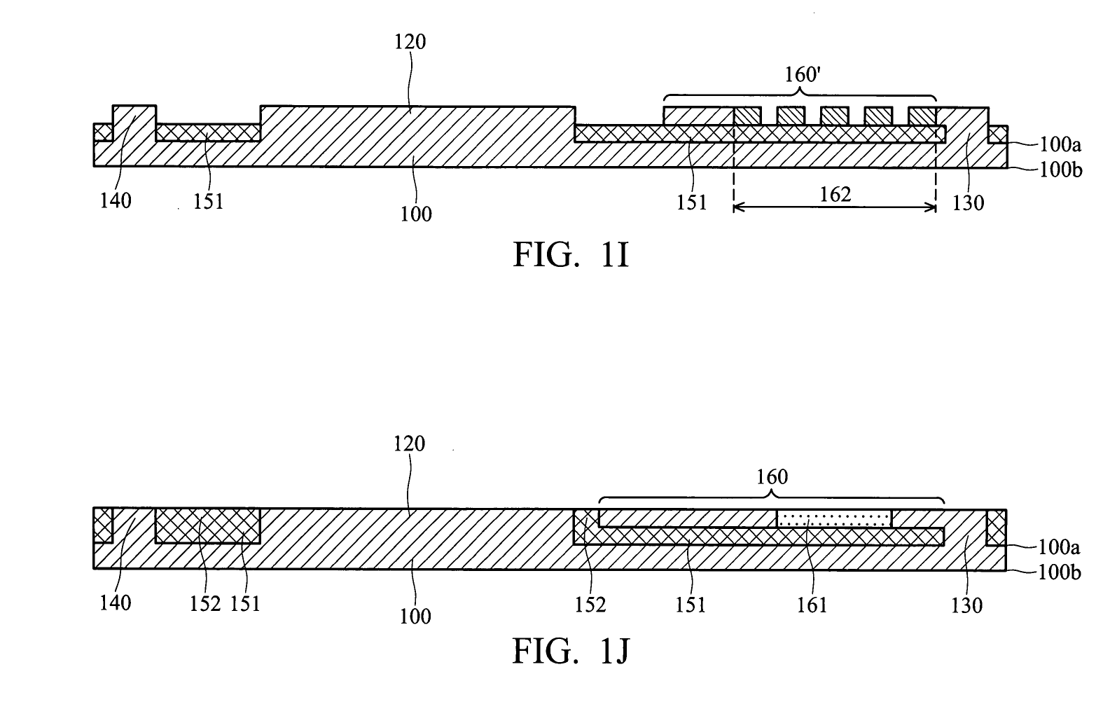

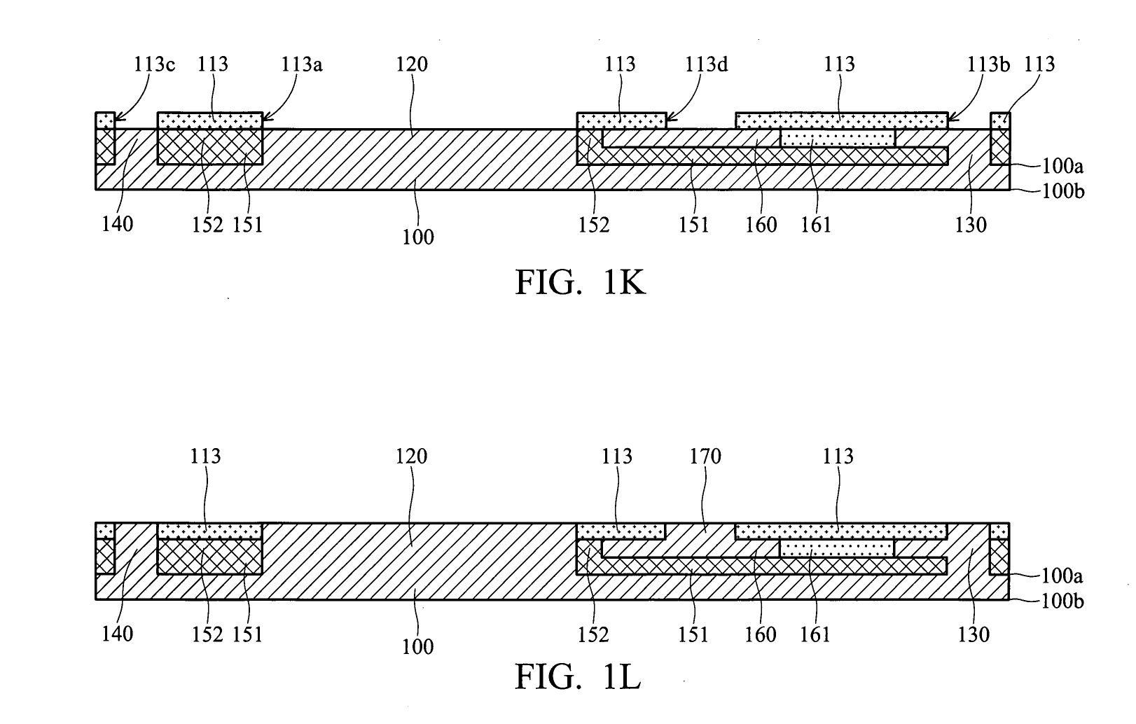

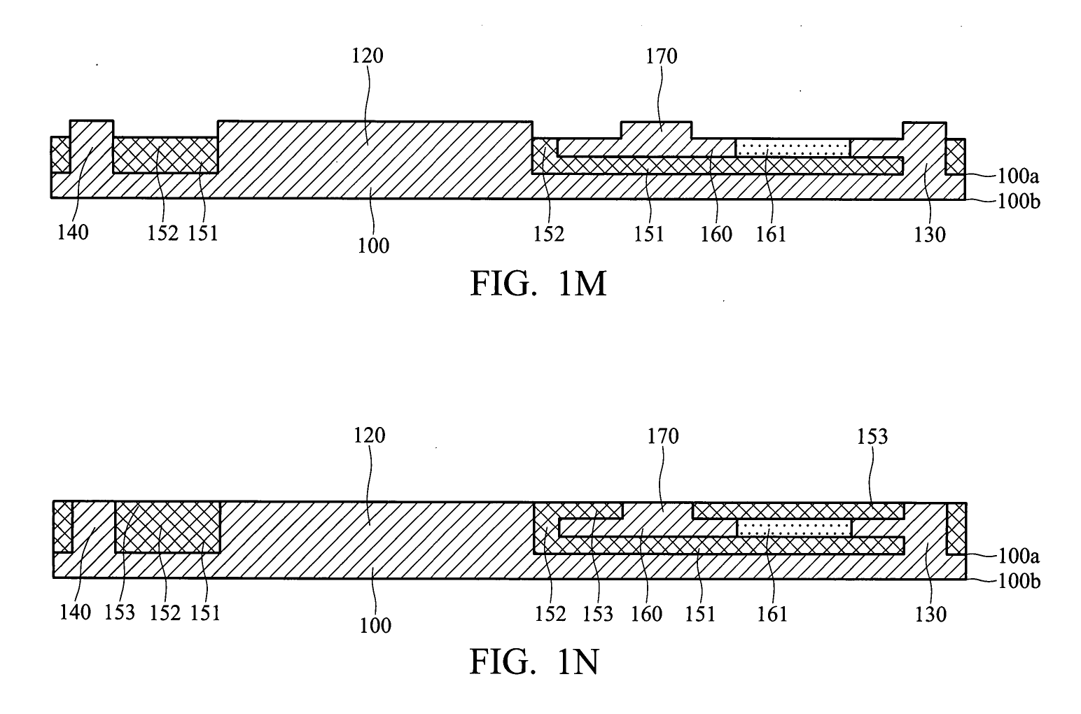

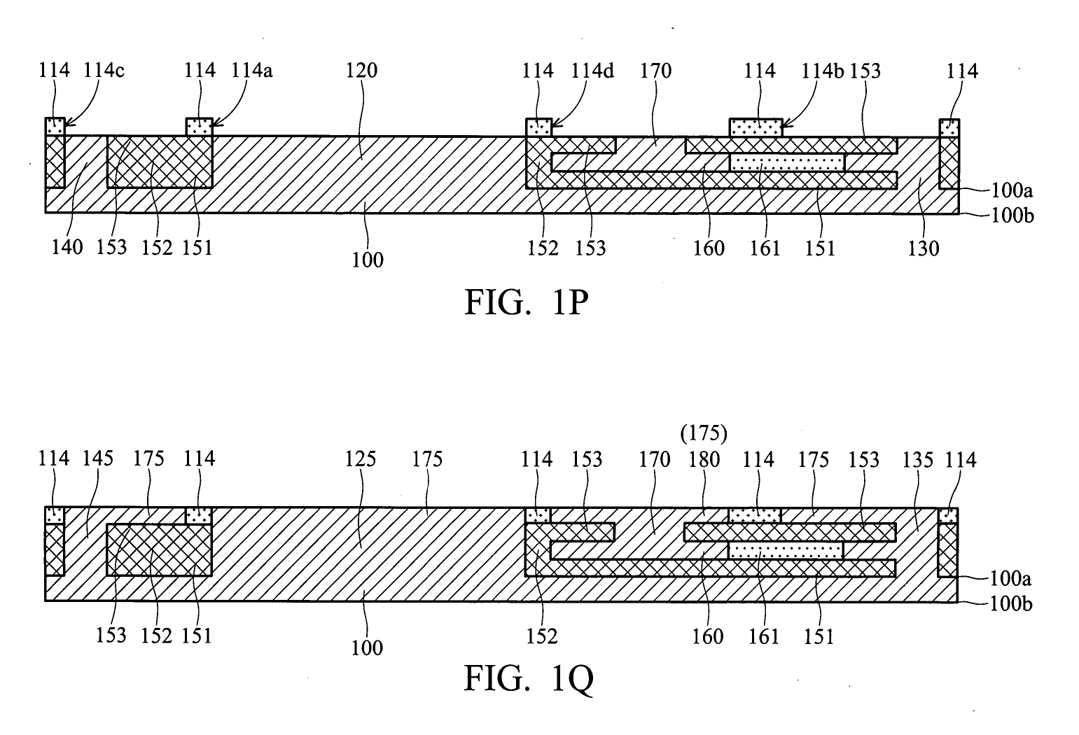

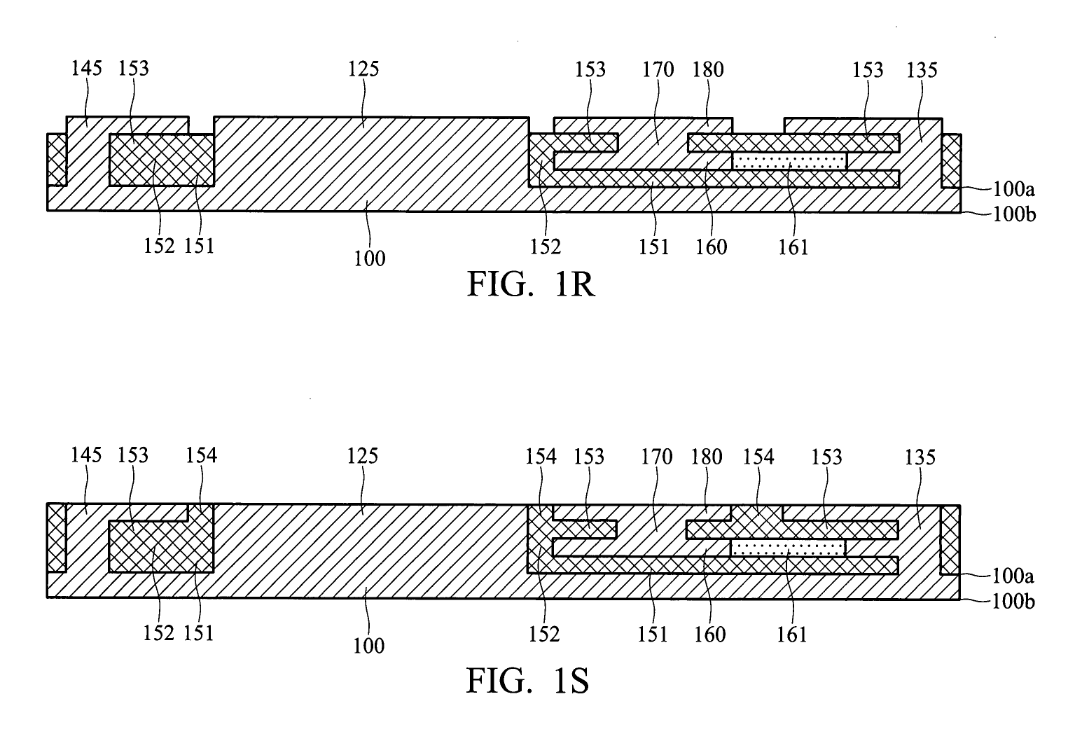

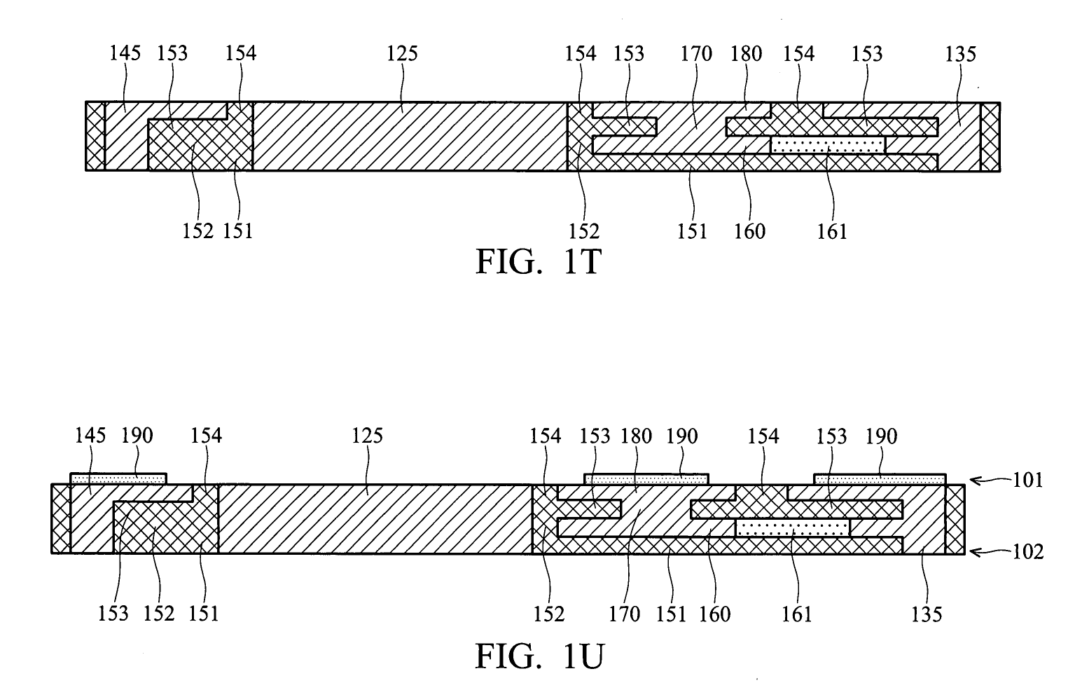

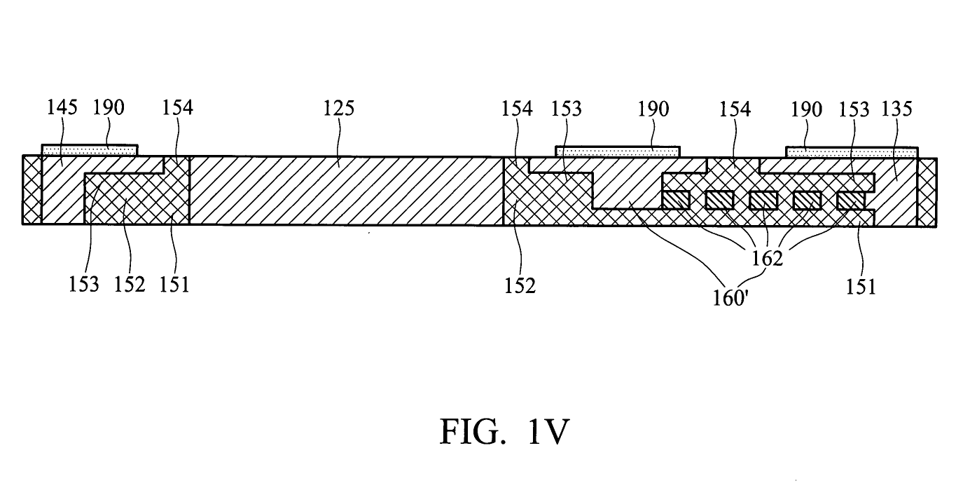

In FIG. 1U, a cross-section of a leadframe with an embedded passive component of a first embodiment of the invention is shown. The leadframe comprises opposite first surface 101 and second surface 102. In this embodiment, the leadframe comprises a base 125, trace line 180, pad 135, wiring 160, and insulating materials 151 through 154.

The base 125 is exposed in the first surface 101 and second surface 102. An active device (not shown), such as a semiconductor chip, photoelectric device, or other device, is attached to the base 125 in a packaging process. The trace line 180, exposed in the first surface 101, is disposed beyond the base 125. An optional solder mask 190 is formed overlying the trace line 180.

The pad 135, exposed in at least the second surface 102, is disposed beyond the trace line 180. The pad 135 can be optionally exposed in the first surface 101 as required. When the pad 135 is exposed in the first surface 101, the optional solder mask 190 can be formed overlying the pad 135, and thus, another active device or a passive device (not shown) can be provided and electrically connect the trace line 180 and pad 135 exposed in the first surface 101.

The wiring 160, comprising a passive component 161, is disposed between the first and second surfaces 101 and 102. The wiring 160 electrically connects the trace line 180 and pad 135. The wiring 160 can be single-layered or multi-layered. The passive component 161 comprises a resistor, inductor, capacitor, or combinations thereof. In this embodiment, the wiring 160 is single-layered, and the passive component 161 is a resistor. The wiring 160 is electrically connected to the trace line 180 by an electrical connection layer 170 therebetween.

The insulating materials 151 through 154 are disposed among the base 125, trace line 180, pad 135, and wiring 160, and completely cover the wiring 160. The insulating material 151, exposed in the second surface 102, is disposed between the base 125 and pad 135, and covers the wiring 160. The insulating material 152 is disposed between the base 125 and wiring 160. The insulating material 153 is disposed between the base 125, electrical connection layer 170, and pad 135, and covers the wiring 160. The insulating material 154, exposed in the first surface 101, is disposed between base 125, trace 180, and pad 135.

In this embodiment, the leadframe may further comprise an optional pad 145, exposed in the first and second surfaces 101 and 102, of the base 125. The respective insulating materials 151 through 154 are disposed between the pad 145 and base 125. The solder mask 190 may be optionally formed overlying the pad 145.

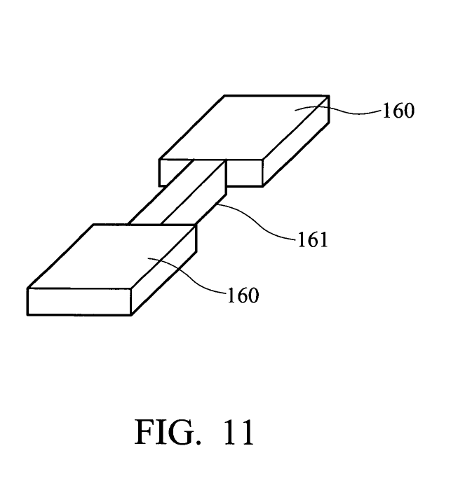

Moreover, the base 125, pads 135, 145, trace line 180, electrical connection layer 170, wiring 160, and passive component 161 are preferably metal, and more preferably copper or copper alloys. As described, the passive component 161 of this embodiment is a resistor and an example thereof is shown in the three-dimensional skeleton diagram of FIG. 11. The passive component 161 is controlled to be thinner than the neighboring wiring 161 during formation of the wiring 161. Thus, resistance of the passive component 161 is larger than that of the neighboring wiring 161 to serve as a resistor.

A wiring 160′ comprising a passive component 162 replaces the wiring 160 of the leadframe of the first embodiment as shown in FIG. 1V, a cross-section of a leadframe with an embedded passive component of a second embodiment of the invention. Details regarding the other elements are the same as those described for FIG. 1U, and thus, are omitted in the following.

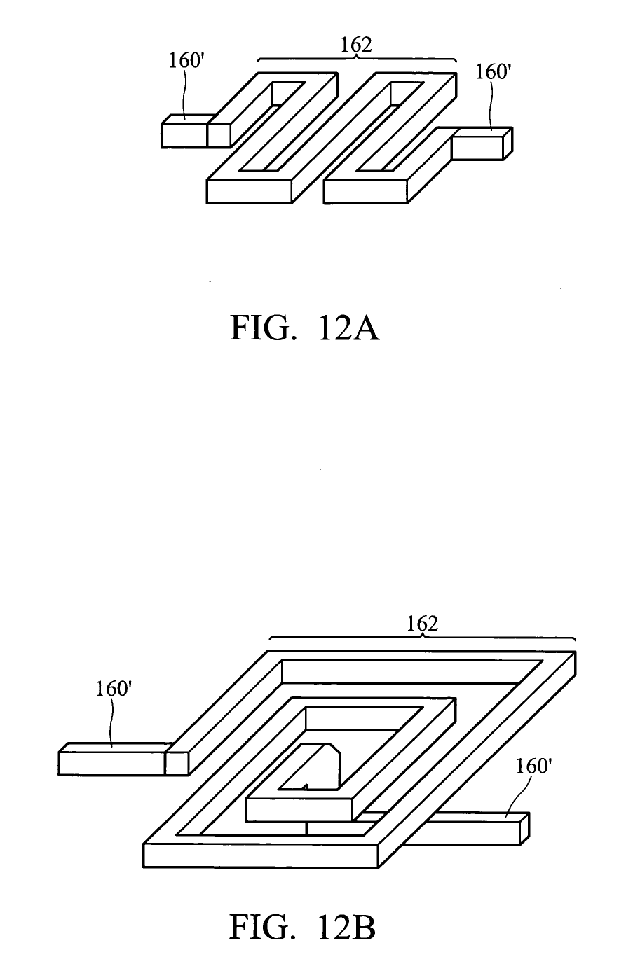

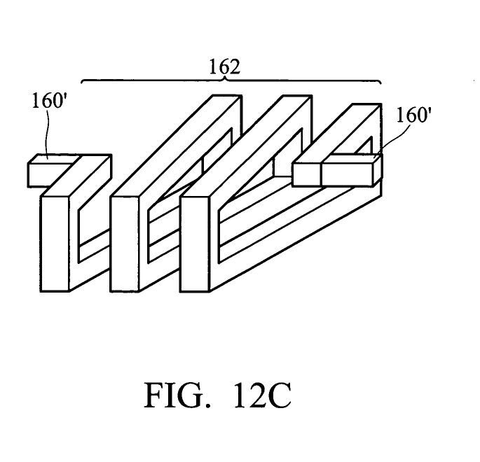

In this embodiment, the passive component 162 is an inductor, the exemplary three three-dimensional skeleton diagrams of which are shown in FIGS. 12A through 12C. The passive component 162 is substantially as thick as the neighboring wiring 160′, but extends more circuitously as required to serve as an inductor. Further, the wiring 160′ and passive component 162 are preferably metal, and more preferably copper or copper alloys.

The following third embodiment describes an exemplary flow for fabricating the leadframes of the first and second embodiments.

FIGS. 1A through 1N and 1P through 1T show cross-sections of a method for fabricating the leadframes of the first and second embodiments of the invention.

In FIG. 1A, a conductive substrate 100, preferably copper, is provided. The conductive substrate 100 comprises a top surface 100a and bottom surface 100b.

A base embryo 120 and pad embryo 130 are formed overlying the top surface 100a of the conductive substrate 100 as shown in FIGS. 1B through 1D. Note that the steps shown in FIGS. 1B through 1D are exemplary, and not intended to limit the scope of the invention. Those skilled in the art will recognize the possibility of using various methods to achieve the base embryo 120 and pad embryo 130 shown in FIG. 1D.

In FIG. 1B, a first patterned mask layer 111, comprising an opening 111a exposing a predetermined region for the base 125 (shown in FIG. 1U or 1V) and opening 111b exposing a predetermined region for the pad 135 (shown in FIG. 1U or 1V), is formed overlying the top surface 100a of the conductive substrate 100. If the pad 145 (shown in FIG. 1U or 1V) is optionally formed, the first patterned mask layer 111 further comprises an opening 111c exposing a predetermined region.

The first patterned mask layer 111 is typically formed by coating a resist layer, followed by exposure and development.

In FIG. 1C, the base embryo 120 and pad embryo 130 are formed overlying the exposed top surface 100a of the conductive substrate 100 by electroplating, electroless plating, or other methods. An optional pad embryo 140 may be formed simultaneously. The pad embryo 130 is disposed beyond the base embryo 120, and the optional pad embryo 140 is disposed beyond the base embryo 120. The base embryo 120, pad embryo 130, and optional pad embryo 140 are preferably substantially the same material as the conductive substrate 100, such as copper.

The first patterned mask layer 111 is then removed as shown in FIG. 1D.

In FIG. 1E, an insulating material 151 is formed overlying the top surface 100a of the conductive substrate 100 by use of the base embryo 120, pad embryo 130, and optional pad embryo 140 as a mask. Put simply, the insulating material 151 is disposed between the base embryo 120 and pad embryo 130, and further between the base embryo 120 and optional pad embryo 140.

The base embryo 120, pad embryo 130, and the optional pad embryo 140 are thickened, electrically connected the pad embryo 130 via a wiring 160 formed as shown in FIGS. 1F through 1H. Note that the steps shown in FIGS. 1F through 1H are exemplary, and not intended to limit the scope of the invention. Those skilled in the art will recognize the possibility of using various methods to achieve the structure shown in FIG. 1H.

In FIG. 1F, a second patterned mask layer 112 is formed overlying the base embryo 120, pad embryo 130, first insulating material 151, and the optional pad embryo 140. The second patterned mask layer 112 comprises an opening 112a exposing the base embryo 120, opening 112b exposing the pad embryo 130 and a predetermined region for the wiring 160, and optional opening 112c exposing the optional pad embryo 140.

In FIG. 1G, the base embryo 120 and pad embryo 130 are thickened, and the wiring 160, electrically connecting the pad embryo 130, is simultaneously formed in the opening 112b (shown in FIG. 1F) by electroplating, electroless plating, or other methods. The optional pad embryo 140 may be thickened simultaneously. The wiring 160, comprising a passive component 161, is disposed beyond the base embryo 120. As described, the passive component 161 is a resistor.

The wiring 160 and materials thickening the base embryo 120, pad embryo 130, and optional pad embryo 140 are preferably substantially the same as the conductive substrate 100, such as copper.

The second patterned mask layer 112 is then removed as shown in FIG. 1H.

Further, in FIG. 1G, a wiring 160′ comprising a passive component 162 may be formed instead of the wiring 160 to provide the structure shown in FIG. 1I. The passive component 162 is an inductor.

Following the step shown in FIG. 1H, a second insulating material 152 is formed overlying the first insulating material 151 by use of the base embryo 120, pad embryo 130, optional pad embryo 140, and wiring 160 as a mask as shown in FIG. 1J. Put simply, the second insulating material 152 is disposed between the base embryo 120 and wiring 160, and further between the base 120 and optional pad embryo 140.

The base embryo 120, pad embryo 130, and further the optional pad embryo 140 are thickened, and an electrical connection layer 160 is formed as shown in FIGS. 1K through 1M. Note that the steps shown in FIGS. 1K through 1M are exemplary, and not intended to limit the scope of the invention. Those skilled in the art will recognize the possibility of using various methods to achieve the structure shown in FIG. 1M.

In FIG. 1K, a third patterned mask layer 113 is formed overlying the base embryo 120, pad embryo 130, second insulating material 152, and further the optional pad embryo 140. The third patterned mask layer 113 comprises an opening 113a exposing the base embryo 120, opening 113b exposing the pad embryo 130, optional opening 113c exposing the optional pad embryo 140, opening 113d exposing at least parts of the wiring 160 which is a predetermined region for the electrical connection layer 170.

In FIG. 1M, the base embryo 120 and pad embryo 130 are thickened, and the electrical connection layer 170 is simultaneously formed in the opening 113d (shown in FIG. 1L) by electroplating, electroless plating, or other methods. The optional pad embryo 140 may be thickened simultaneously. The electrical connection layer 170 and materials thickening the base embryo 120, pad embryo 130, and optional pad embryo 140 are preferably substantially the same as the conductive substrate 100, such as copper.

The third patterned mask layer 113 is then removed as shown in FIG. 1M.

A third insulating material 153 is formed covering the wiring 160 and the second insulating material 152 by use of the base embryo 120, pad embryo 130, optional pad embryo 140, and electrical connection layer 170 as a mask as shown in FIG. 1N. Put simply, the third insulating material 153 is disposed between the base embryo 120, electrical connection layer 170, and pad embryo 130 and further between the base 120 and optional pad embryo 140.

A conductive layer 175 is formed overlying the base embryo 120, pad embryo 130, electrical connection layer 170, and further the optional pad embryo 140 as shown in FIGS. 1P through 1R. The combined conductive layer 175 and base embryo 120 form a base 125. The combined conductive layer 175 and pad embryo 130 form a pad 135. The combined conductive layer 175 and optional pad embryo 140 form an optional pad 145. The conductive layer 175 overlying the electrical connection layer 170 acts as a trace line 180. Note that the steps shown in FIGS. 1P through 1R are exemplary, and not intended to limit the scope of the invention. Those skilled in the art will recognize the possibility of using various methods to achieve the structure shown in FIG. 1R.

In FIG. 1P, a fourth patterned mask layer 114 is formed overlying the base embryo 120, pad embryo 130, electrical connection layer 170, third insulating material 153, and the optional pad embryo 140. The fourth patterned mask layer 114 comprises an opening 114a exposing the base embryo 120, opening 114b exposing the pad embryo 130, opening 114d exposing the electrical connection layer 170, and optional opening 114c exposing the optional pad embryo 140.

In FIG. 1Q, the conductive layer 175 is formed by electroplating, electroless plating, or other methods. Thus, the base 125, pad 13.5, trace line 180, and optional pad 145 are formed as described. The trace line 180 is disposed beyond the base 125, and the pad 135 is disposed beyond the trace line 180. The conductive layer 175 is preferably substantially the same material as the conductive substrate 100, such as copper.

The fourth patterned mask layer 114 is then removed as shown in FIG. 1R.

In FIG. 1S, a fourth insulating material 154 is formed overlying the third insulating material 153 by use of the base 125, pad 135, optional pad 145, and trace line 180 as a mask. Put simply, the fourth insulating material 154 is disposed between the base 125, trace line 180, and pad 135, and further between the base 125 and optional pad 145.

In FIG. 1T, at least the conductive substrate 100 underlying the first insulating material 151 is removed. In this embodiment, the conductive substrate 100 is completely removed by etching or grinding. A method removing the conductive substrate 100 underlying the first insulating material 151 only is disclosed in a subsequently described embodiment.

A solder mask 190 shown in FIG. 1U is optionally formed overlying the trace line 180, pad 135, and/or optional pad 145 as required by use of a method such as stencil printing.

Further, when the wiring 160′ comprising the passive component 162 is formed instead of the wiring 160, the leadframe shown in FIG. 1V is achieved during steps substantially equivalent to description for FIGS. 1J through 1N and 1P through 1T and the aforementioned step for the solder mask 190 following that shown in FIG. 1I.

In the following fourth embodiment of the invention, steps for removal of only the conductive substrate 100 underlying the first insulating material 151 following that shown in FIG. 1S are described.

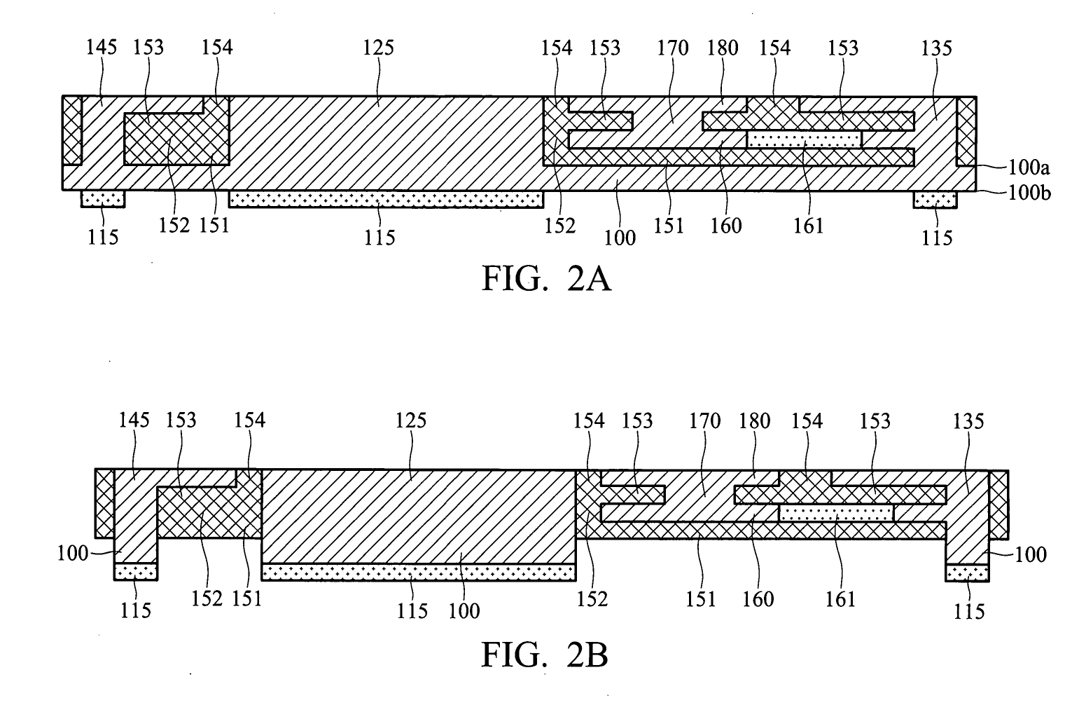

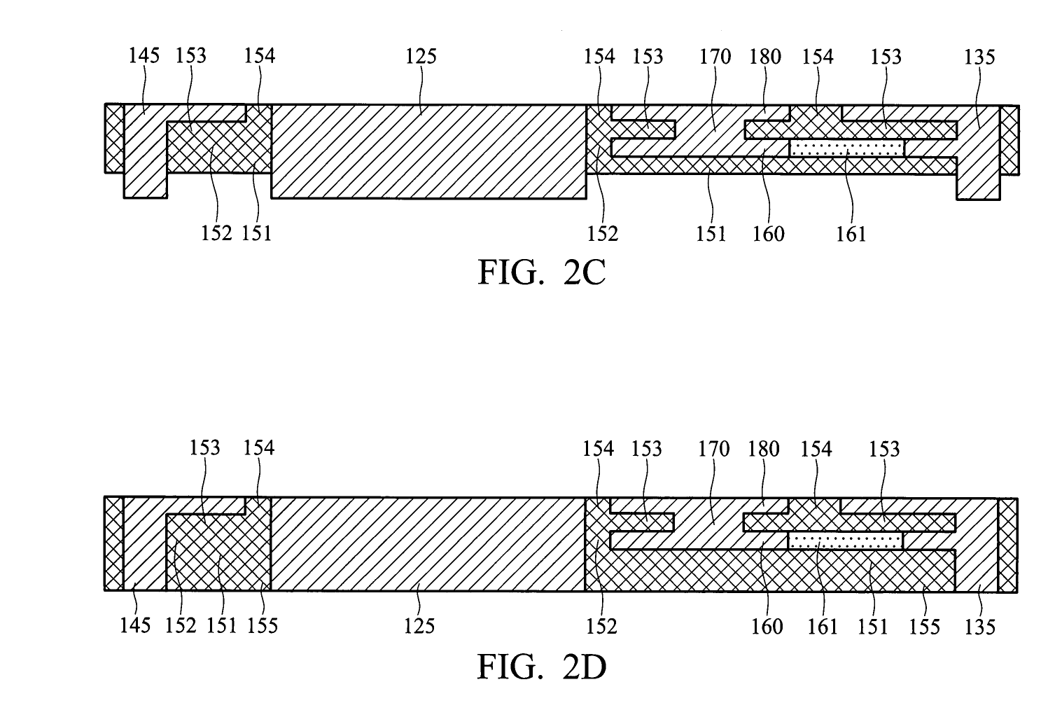

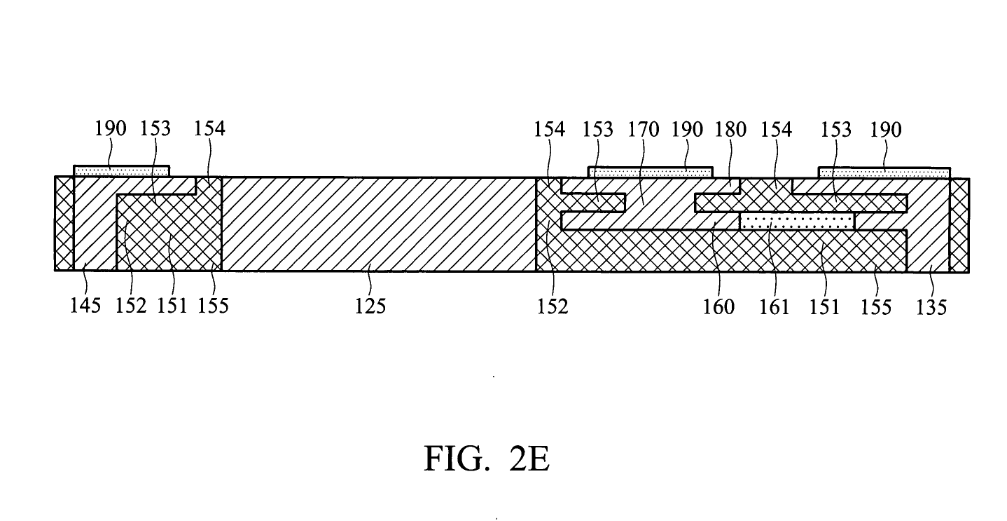

In FIGS. 2A through 2E, cross-sections of a method for fabricating the leadframes of the first and second embodiments of the invention are shown.

In FIG. 2A, following FIG. 1S, a fifth patterned mask layer 115 is formed underlying the bottom surface 100b of the conductive substrate 100, exposing the conductive substrate 100 underlying the first insulating material 151.

In FIG. 2B, the exposed conductive substrate 100 is removed. Thus, the remaining conductive substrate becomes part of the respective base 125, pad 135, and optional pad 145.

The fifth patterned mask layer 115 is then removed as shown in FIG. 2C.

In FIG. 2D, a fifth insulating material 155 is optionally formed in regions of the removed conductive substrate 100 by use of the remaining conductive substrate 100 as a mask.

In FIG. 2E, a solder mask 190 is optionally formed overlying the trace line 180, pad 135, and/or optional pad 145 as required by use of a method such as stencil printing. Thus, a leadframe equivalent to that shown in FIG. 1U is achieved.

Similarly, when the wiring 160′ comprising the passive component 162 is formed instead of the wiring 160, the leadframe shown in FIG. 1V is achieved during steps substantially equivalent to description for FIGS. 1J through 1S, 2A through 2E following that shown in FIG. 1I.

In the following fifth embodiment, another method for fabricating the leadframes of the first and second embodiments of the invention is disclosed.

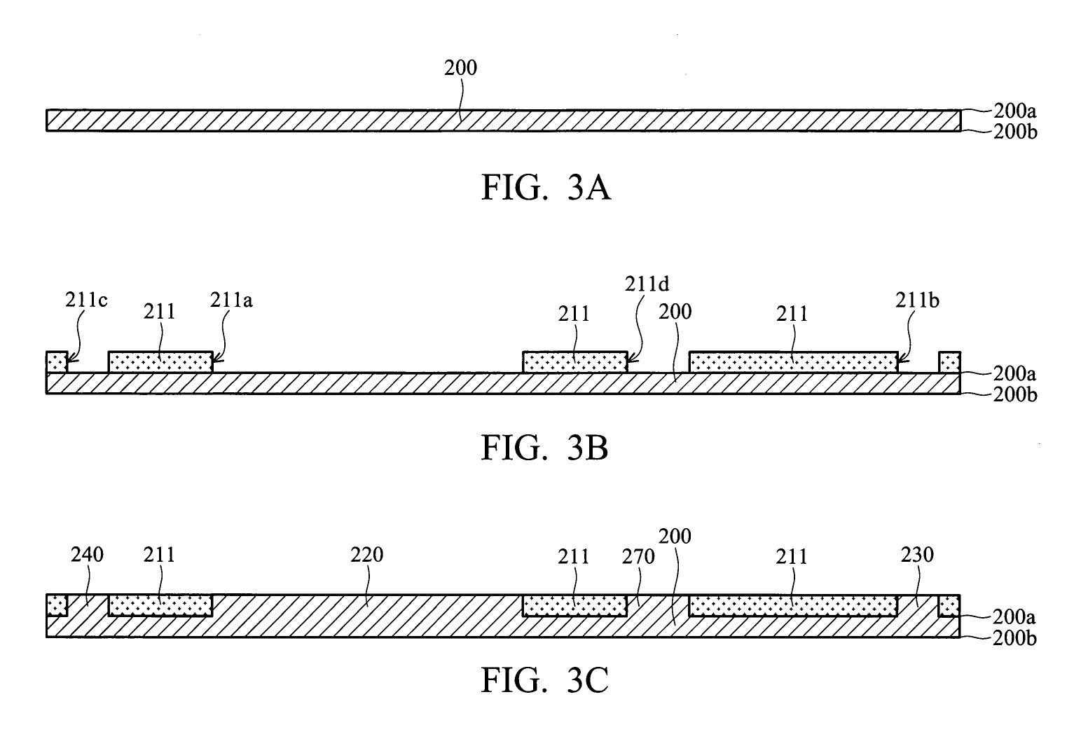

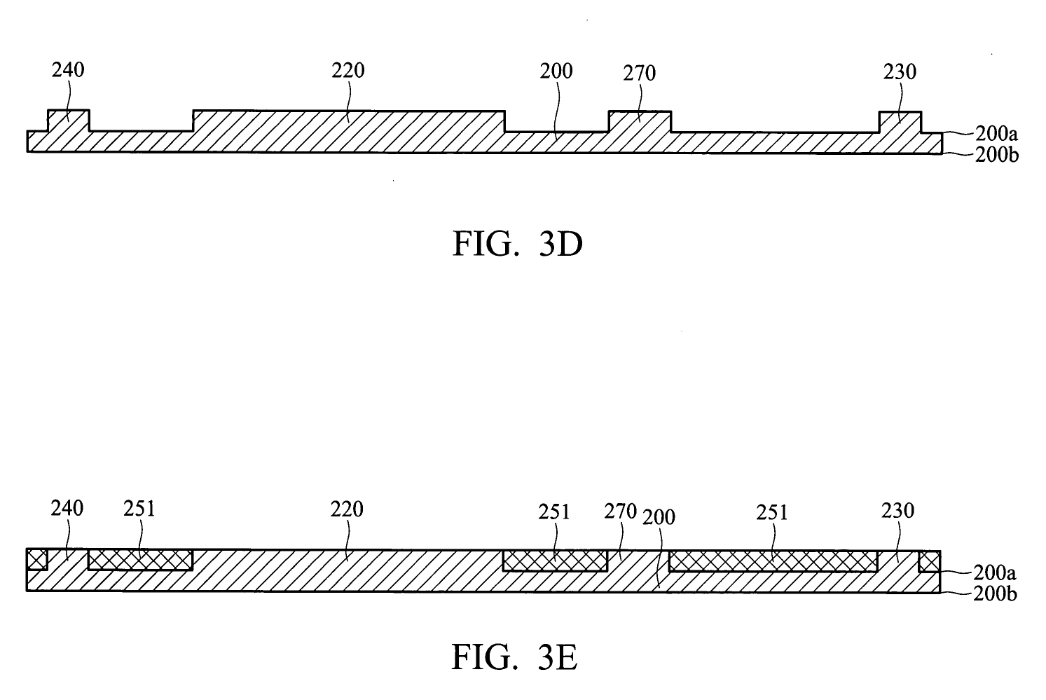

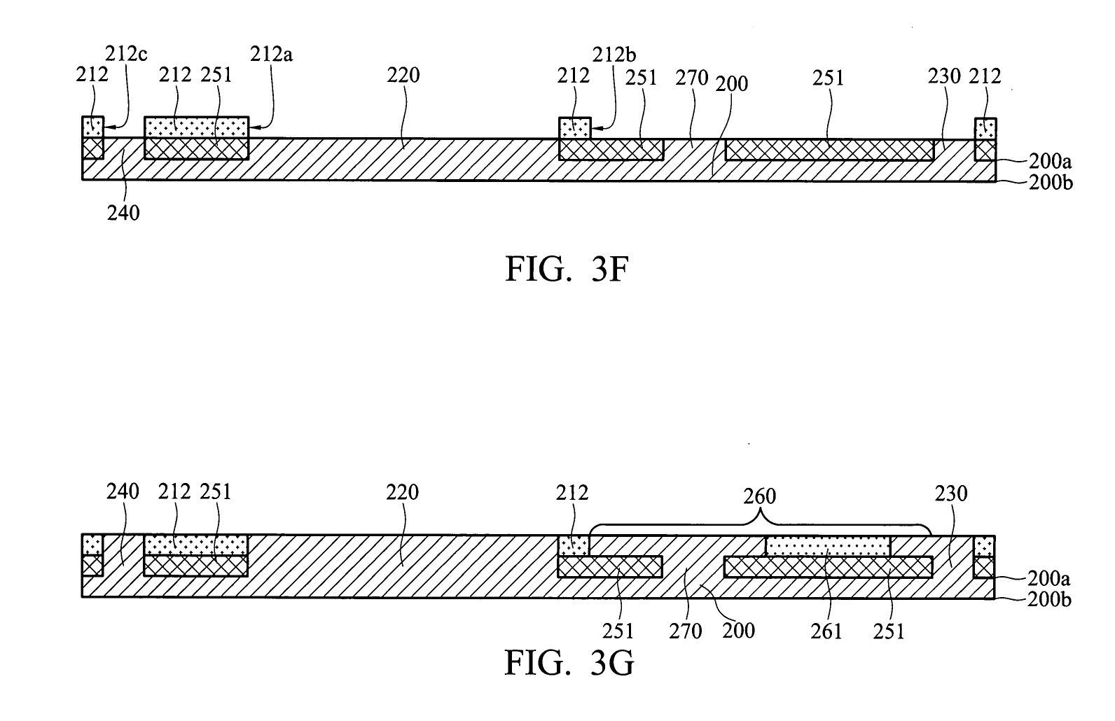

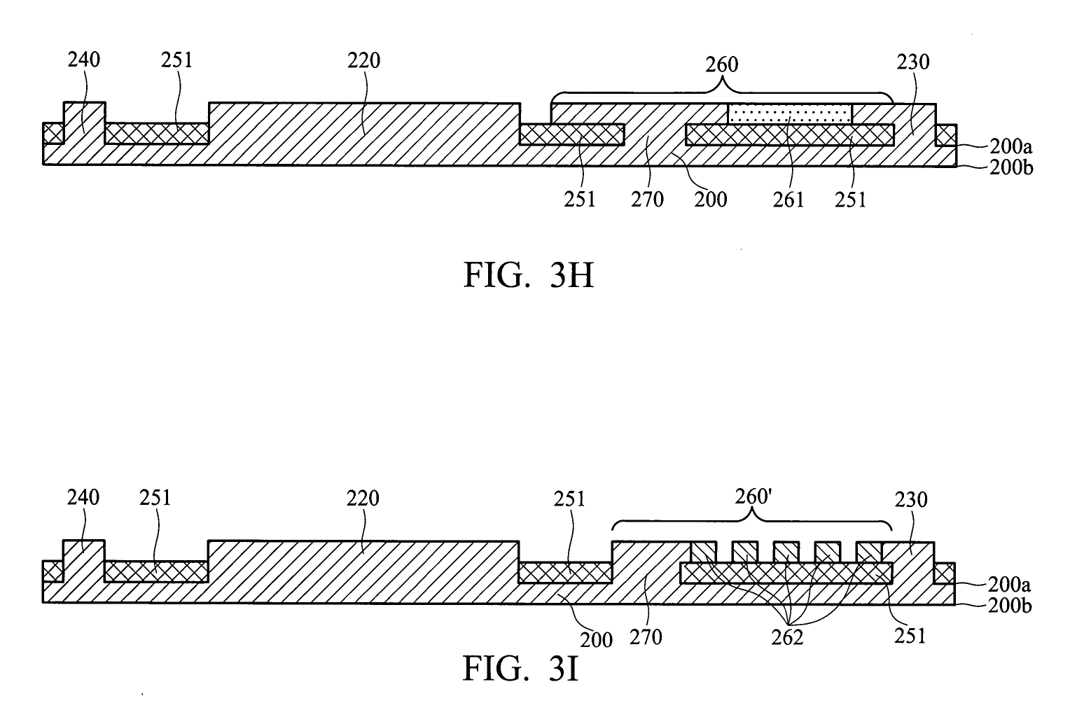

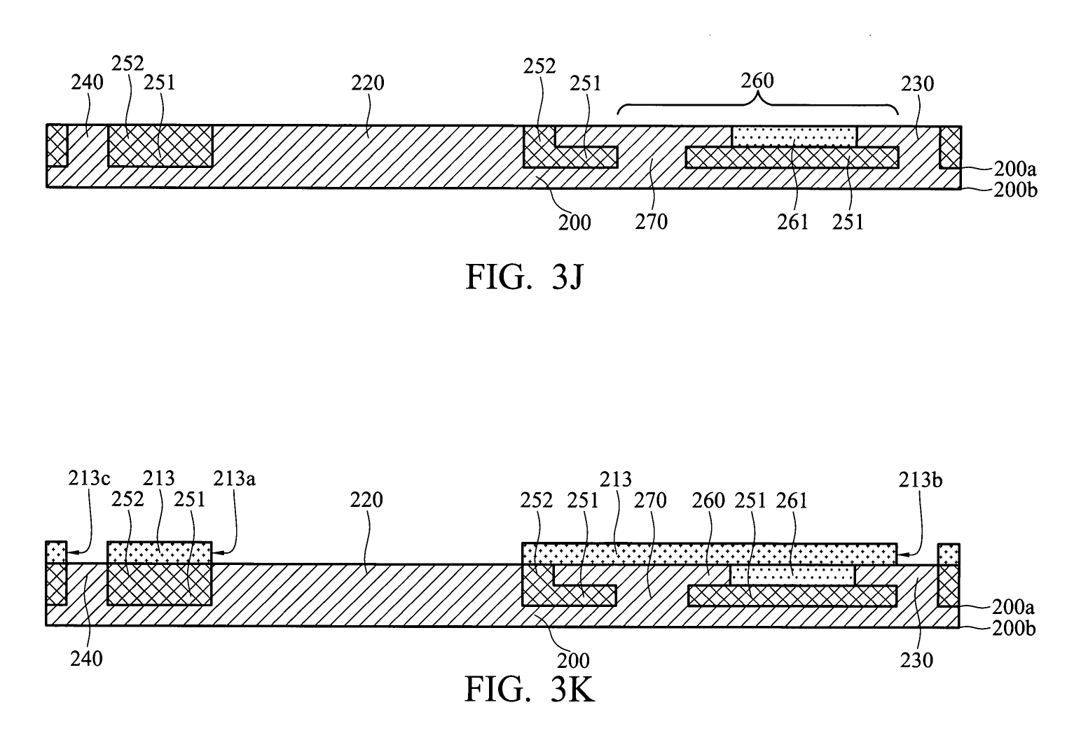

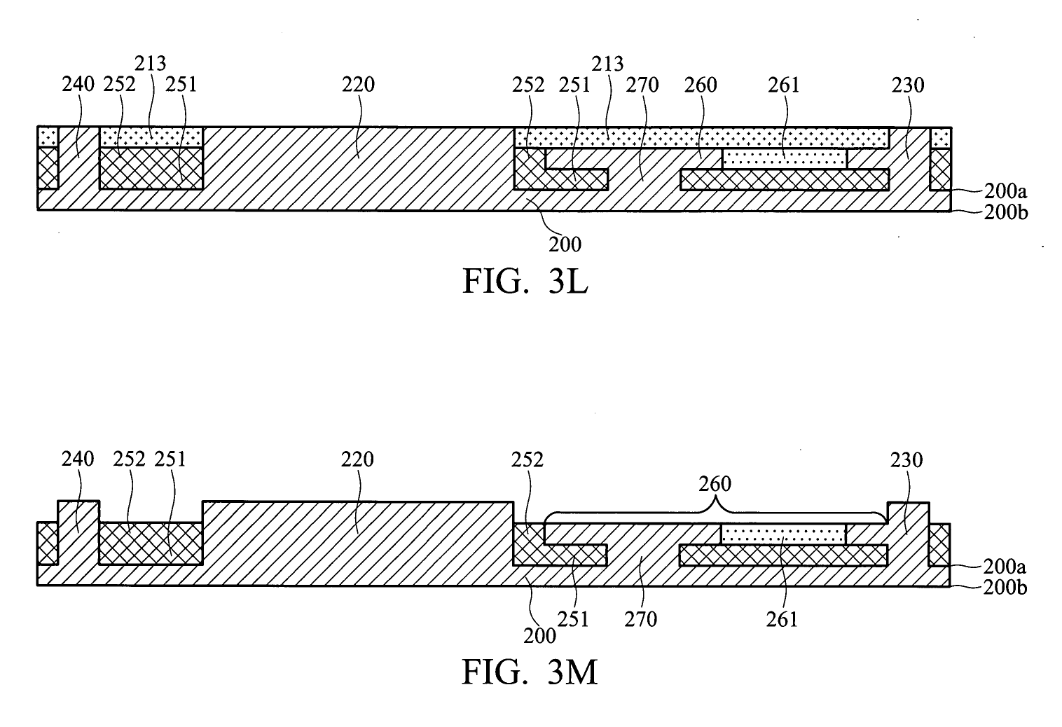

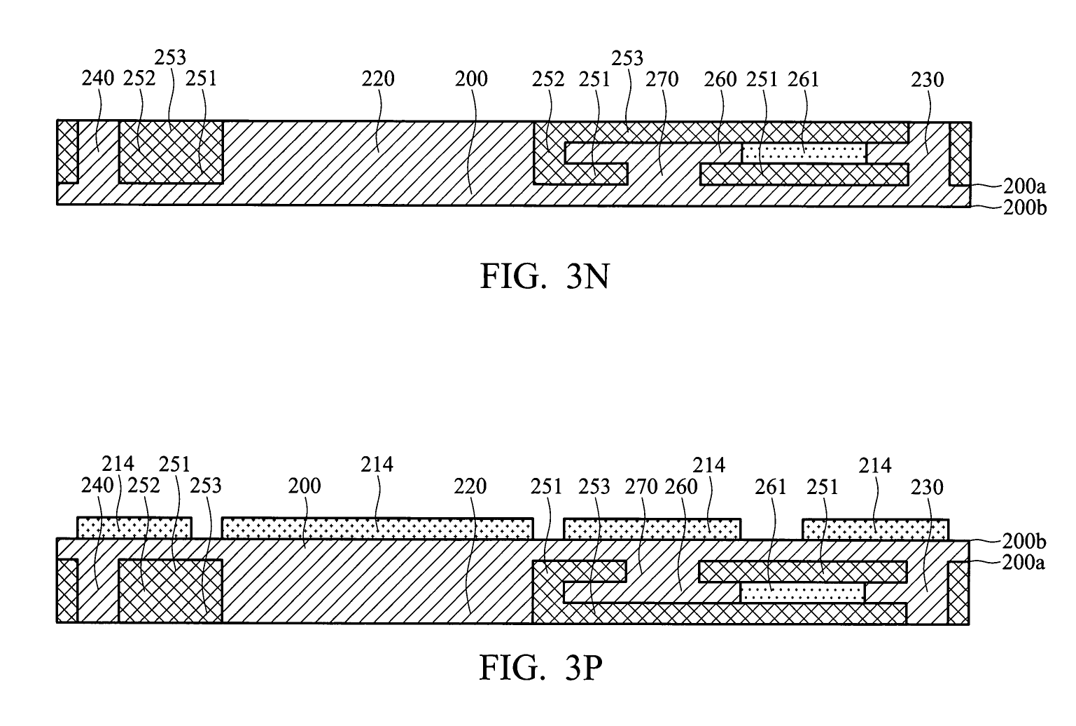

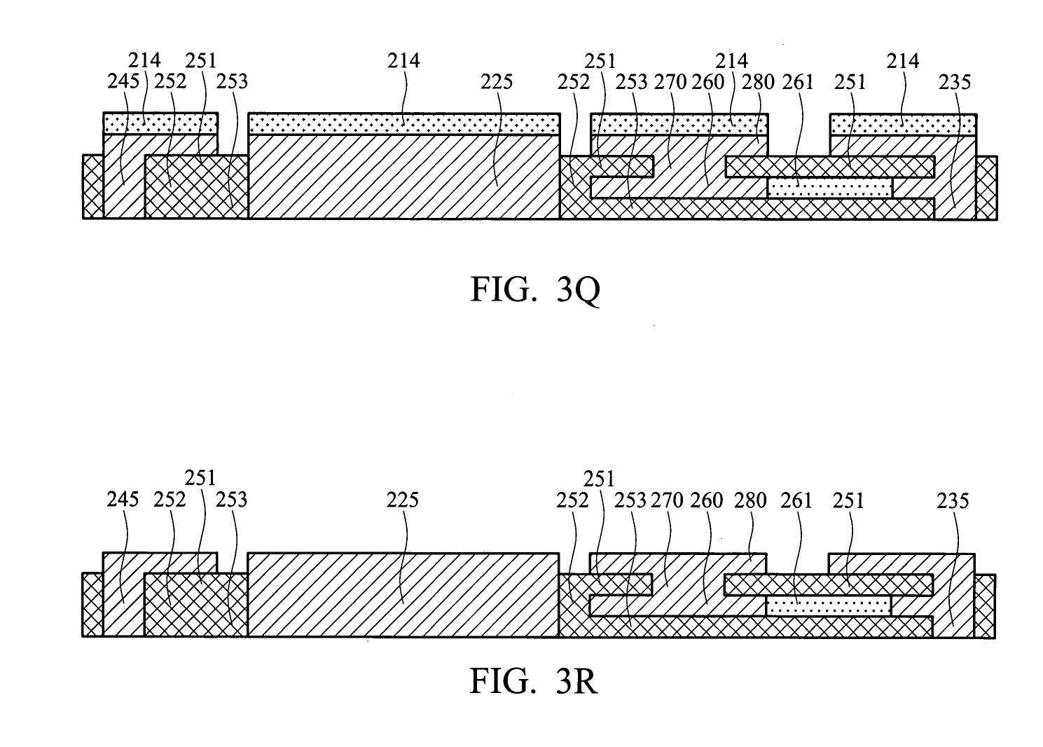

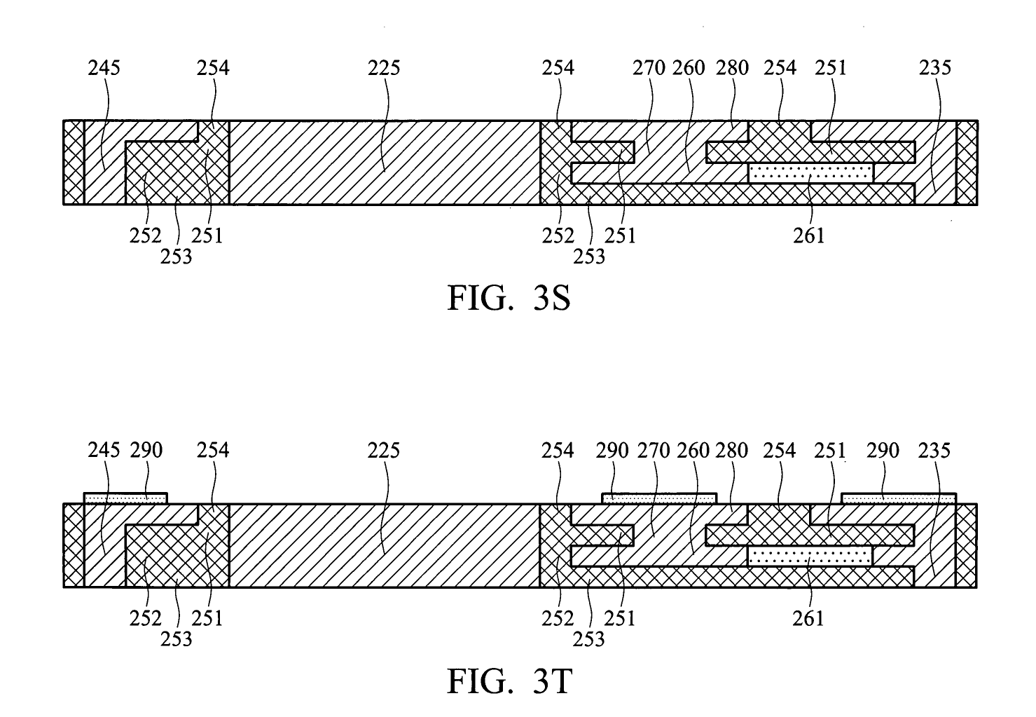

In FIGS. 3A through 3N and 3P through 3T, cross-sections of a method for fabricating the leadframes of the first and second embodiments of the invention are shown.

In FIG. 3A, a conductive substrate 200, preferably copper, is provided. The conductive substrate 200 comprises a top surface 200a and bottom surface 200b.

A base embryo 220, electrical connection layer 270, and pad embryo 230 are formed overlying the top surface 200a of the conductive substrate 200 as shown in FIGS. 3B through 3D. Note that the steps shown in FIGS. 3B through 3D are exemplary, and not intended to limit the scope of the invention. Those skilled in the art will recognize the possibility of using various methods to achieve a base embryo 220, electrical connection layer 270, and pad embryo 230 shown in FIG. 3D.

In FIG. 3B, a first patterned mask layer 211, comprising an opening 211a exposing a predetermined region for a base 225 (shown in FIG. 3T), opening 211b exposing a predetermined region for a pad 235 (shown in FIG. 3T), and opening 211d exposing a predetermined region for the electrical connection layer 270, is formed overlying the top surface 200a of the conductive substrate 200. When the pad 245 (shown in FIG. 3T) is optionally formed, the first patterned mask layer 211 further comprises an opening 211c exposing a predetermined region.

The first patterned mask layer 211 is typically formed by coating a resist layer, followed by exposure and development.

In FIG. 3C, the base embryo 220, electrical connection layer 270, and pad embryo 230 are formed overlying the exposed top surface 200a of the conductive substrate 200 by electroplating, electroless plating, or other methods. An optional pad embryo 240 may be formed simultaneously. The electrical connection layer 270 is disposed beyond the base embryo 220, the pad embryo 230 is disposed beyond the electrical connection layer 270, and the optional pad embryo 240 is disposed beyond the base embryo 220. The, base embryo 220, electrical connection layer 270, pad embryo 230, and optional pad embryo 240 are preferably substantially the same material as the conductive substrate 200, such as copper.

The first patterned mask layer 211 is then removed as shown in FIG. 3D.

In FIG. 3E, a first insulating material 251 is formed overlying the top surface 200a of the conductive substrate 200 by use of the base embryo 220, electrical connection layer 270, pad embryo 230, and optional pad embryo 240 as a mask. Put simply, the first insulating material 251 is disposed between the base embryo 220, electrical connection layer 270, and pad embryo 230, and further between the base embryo 220 and optional pad embryo 240.

The base embryo 220, pad embryo 230, and further the optional pad embryo 240 are thickened, and a wiring 260 electrically connecting the pad embryo 230 and electrical connection layer 270 is formed as shown in FIGS. 3F through 3H. Note that the steps shown in FIGS. 3F through 3H are exemplary, and not intended to limit the scope of the invention. Those skilled in the art will recognize the possibility of using various methods to achieve the structure shown in FIG. 3H.

In FIG. 3F, a second patterned mask layer 212 is formed overlying the base embryo 220, pad embryo 230, electrical connection layer 270, first insulating material 251, and further the optional pad embryo 240. The second patterned mask layer 212 comprises an opening 212a exposing the base embryo 220, opening 212b exposing the pad embryo 230 and a predetermined region for the wiring 260, and optional opening 212c exposing the optional pad embryo 240.

In FIG. 3G, the base embryo 220 and pad embryo 230 are thickened, and the wiring 260, electrically connecting the pad embryo 230 and electrical connection layer 270, is simultaneously formed in the opening 212b (shown in FIG. 3F) by electroplating, electroless plating, or other methods. The optional pad embryo 240 may be thickened simultaneously. The wiring 260, comprising a passive component 261, is disposed beyond the base embryo 220. The passive component 261 is a resistor, equivalent to the passive component 161.

The wiring 260 and materials thickening the base embryo 220, pad embryo 230, and optional pad embryo 240 are preferably substantially the same as the conductive substrate 200, such as copper.

The second patterned mask layer 212 is then removed as shown in FIG. 3H.

Further, in FIG. 3G, a wiring 260′ comprising a passive component 262 may be formed instead of the wiring 260 to provide the structure shown in FIG. 3I. The passive component 262 is an inductor.

Following the step shown in FIG. 3H, a second insulating material 252 is formed overlying the first insulating material 151 by use of the base embryo 220, pad embryo 230, optional pad embryo 240, and wiring 260 as a mask as shown in FIG. 3J. Put simply, the second insulating material 252 is disposed between the base embryo 220 and wiring 260, and further between the base 220 and optional pad embryo 240.

The base embryo 220, pad embryo 230, and further the optional pad embryo 240 are thickened as shown in FIGS. 3K through 3M. Note that the steps shown in FIGS. 3K through 3M are exemplary, and not intended to limit the scope of the invention. Those skilled in the art will recognize the possibility of using various methods to achieve the structure shown in FIG. 3M.

In FIG. 3K, a third patterned mask layer 213 is formed overlying the base embryo 220, pad embryo 230, second insulating material 252, and further the optional pad embryo 240. The third patterned mask layer 213 comprises an opening 213a exposing the base embryo 220, opening 213b exposing the pad embryo 230, and optional opening 213c exposing the optional pad embryo 240.

In FIG. 3M, the base embryo 220 and pad embryo 230 are thickened by electroplating, electroless plating, or other methods. The optional pad embryo 240 may be thickened simultaneously. Materials thickening the base embryo 220, pad embryo 230, and optional pad embryo 240 are preferably substantially the same as the conductive substrate 200, such as copper.

The third patterned mask layer 213 is then removed as shown in FIG. 3M.

A third insulating material 253 is formed covering the wiring 260 and the second insulating material 252 by use of the base embryo 220, pad embryo 230, and optional pad embryo 240 as a mask as shown in FIG. 3N. Put simply, the third insulating material 253 is disposed between the base embryo 220 and pad embryo 230 and further between the base 220 and optional pad embryo 240.

Following FIG. 3N, the structures shown in subsequent figures are flipped as compared to that shown in FIG. 3N.

Parts of the conductive substrate 200 are removed, resulting in combination of the base embryo 220 and the underlying conductive substrate 200 being a base 225, formation of a trace line 280 electrically connecting to the wiring 260 via the electrical connection layer 270, and combination of the pad embryo 230 and the underlying conductive substrate 200 being a pad 235 as shown in FIGS. 3P through 3R. An optional pad 245 may be formed simultaneously resulting from combination of the optional pad embryo 240 and the underlying conductive substrate 200. Note that the steps shown in FIGS. 3P through 3R are exemplary, and not intended to limit the scope of the invention. Those skilled in the art will recognize the possibility of using various methods to achieve the structure shown in FIG. 3R.

In FIG. 3P, a fourth patterned mask layer 214 is formed underlying the bottom surface 200b of the conductive substrate 200, covering the conductive substrate 200 underlying the respective base embryo 220, pad embryo 230, electrical connection layer 270, and further the optional pad embryo 240.

In FIG. 3Q, the conductive substrate 200 not covered by the fourth patterned mask layer 214 is removed by a method such as etching to form the base 225, pad 235, and optional pad 245 as described. Further, the remaining conductive substrate 200 underlying the electrical connection layer 270 becomes the trace line 280 electrically connecting to the wiring 260 via the electrical connection layer 270. The trace line 280 is disposed beyond the base 225, the pad 235 is disposed beyond the trace line 280, and the optional pad 245 is disposed beyond the base 225.

The fourth patterned mask layer 214 is then removed as shown in FIG. 3R.

In FIG. 3S, a fourth insulating material 254 is formed covering the first insulating material 251 by use of the base 225, pad 235, optional pad 245, and trace line 280 as a mask. Put simply, the fourth insulating material 254 is disposed between the base 225, trace line 280, and pad 235, and further between the base 225 and optional pad 245.

In FIG. 3T, a solder mask 290 is optionally formed overlying the trace line 280, pad 235, and/or optional pad 245 as required by use of a method such as stencil printing.

Further, when the wiring 260′ comprising the passive component 262 is formed instead of the wiring 260, the leadframe shown in FIG. 1V is achieved during steps substantially equivalent to description for FIGS. 3J through 3T following that shown in FIG. 3I.

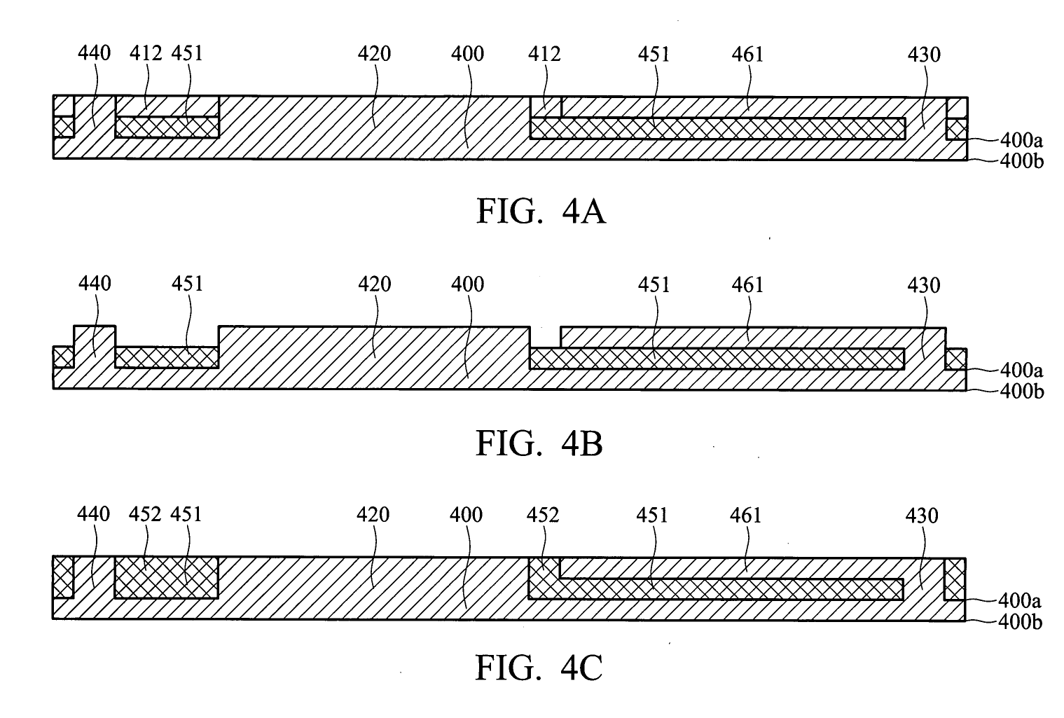

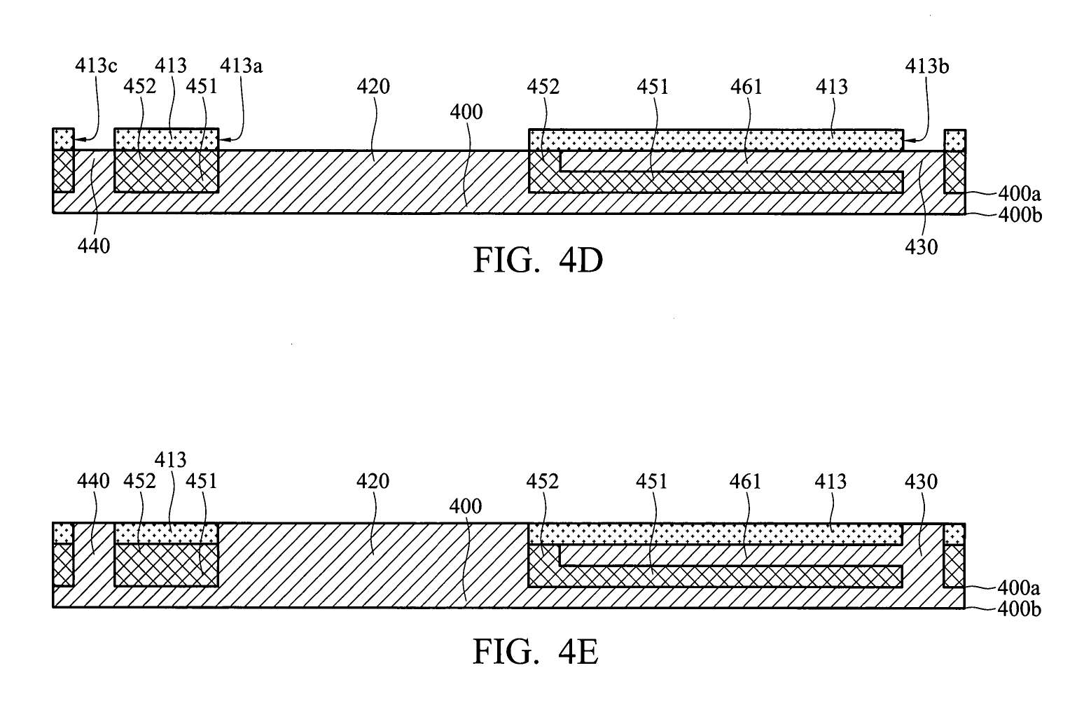

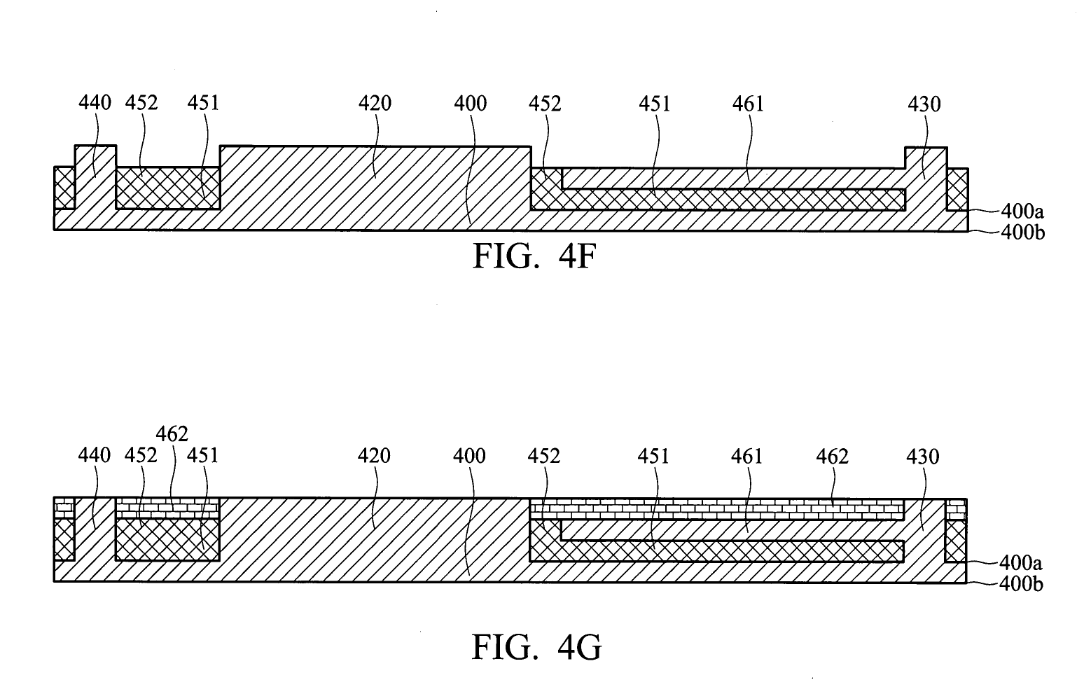

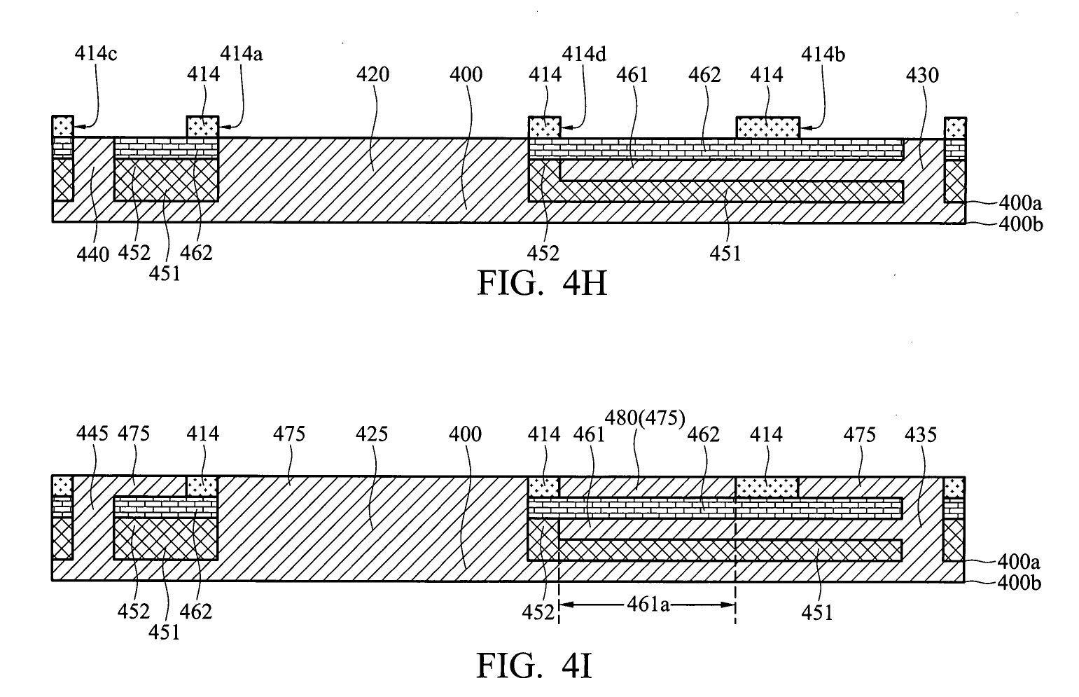

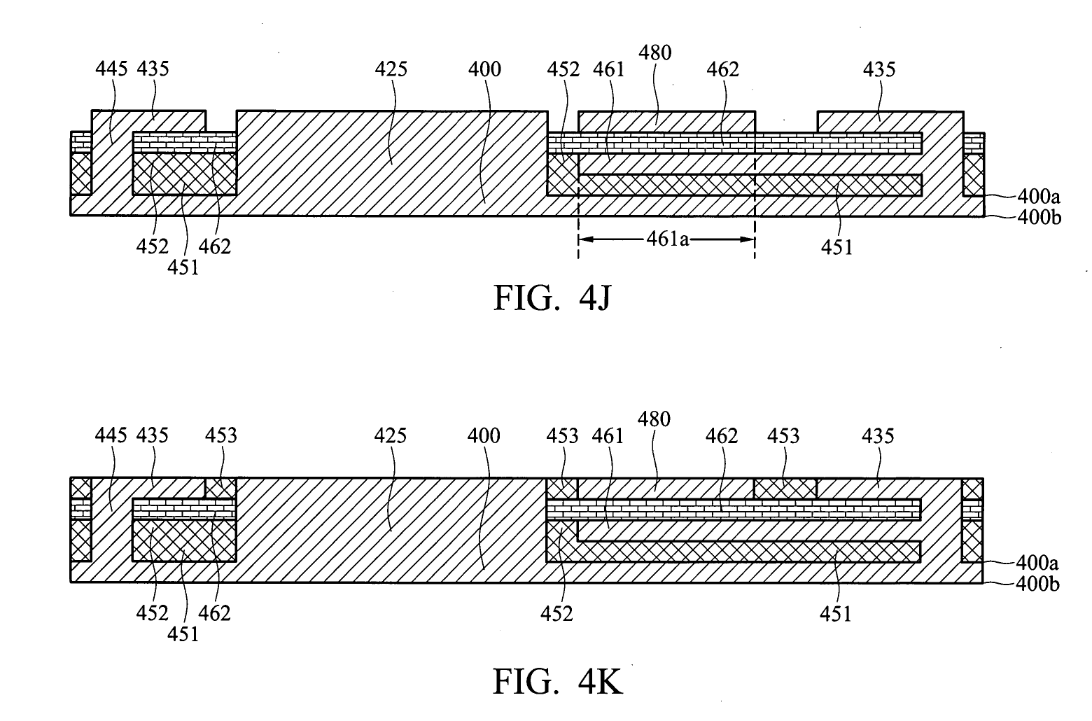

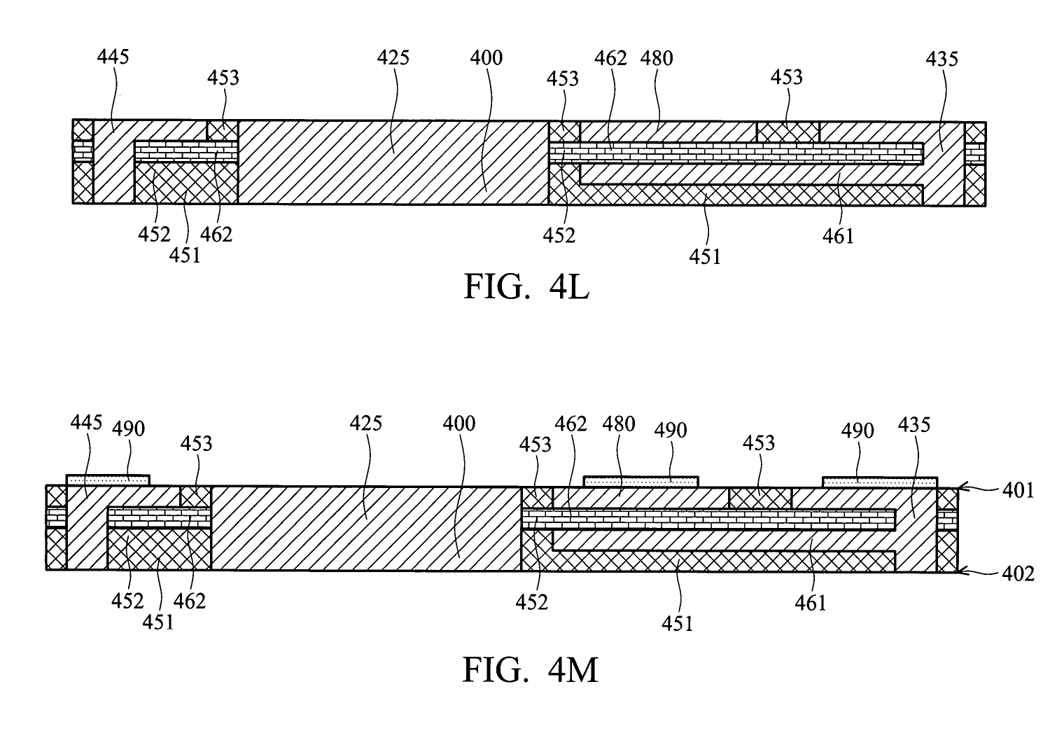

In FIG. 4M, a cross-section of a leadframe with an embedded passive component of a sixth embodiment of the invention is shown. Details regarding the first surface 401, second surface 402, base 425, pad 435, optional pad 445, first insulating material 451, second insulating material 452, third insulating material 453, trace line 480, and solder mask 490 are the same as the respective first surface 101, second surface 102, base 125, pad 135, optional pad 145, first insulating material 151, second insulating material 152, fourth insulating material 154, trace line 180, and solder mask 190 described for FIG. 1U, and thus, are omitted in the following.

In this embodiment, a wiring 461, electrically connecting the pad 435, is disposed underlying the trace line 480. A dielectric material 462 is disposed between at least parts of the trace line 480 and at least parts of the wiring 461. Thus, an embedded capacitor comprising the trace line 480, dielectric material 462, and wiring 461 is formed.

The following seventh embodiment describes an exemplary flow for fabricating the leadframes of the first and second embodiments.

In FIGS. 4A through 4L, cross-sections of a method for fabricating the leadframes of the sixth embodiment of the invention are shown.

In FIG. 4A, a conductive substrate 400, preferably copper, is provided. The conductive substrate 400 comprises a top surface 400a and bottom surface 400b. Details regarding the base embryo 420, pad embryo 430, optional pad embryo 440, first insulating material 451, and second patterned mask layer 412 are the same as the respective base embryo 125, pad embryo 135, optional pad embryo 145, first insulating material 151, and second patterned mask layer 112 described in FIGS. 1B through 1F, and thus, are omitted in the following.

In FIG. 4A, the base embryo 420 and pad embryo 430 are thickened, and the wiring 461, electrically connecting the pad embryo 430, is simultaneously formed in the opening 412b (equivalent to the opening 412b in FIG. 1F) by electroplating, electroless plating, or other methods. The optional pad embryo 440 may be thickened simultaneously. The wiring 461 is disposed beyond the base embryo 120. The wiring 461 may further comprise a passive component (not shown) such as a resistor, inductor, capacitor, or combinations thereof.

The wiring 461 and materials thickening the base embryo 420, pad embryo 430, and optional pad embryo 440 are preferably substantially the same as the conductive substrate 100, such as copper.

The second patterned mask layer 412 is then removed as shown in FIG. 4B.

In FIG. 4C, a second insulating material 452 is formed overlying the first insulating material 451 by use of the base embryo 420, pad embryo 430, optional pad embryo 440, and wiring 461 as a mask. Put simply, the second insulating material 452 is disposed between the base embryo 420 and wiring 461, and further between the base 420 and optional pad embryo 440.

The base embryo 420, pad embryo 430, and further the optional pad embryo 440 are thickened as shown in FIGS. 4D through 4F. Note that the steps shown in FIGS. 4D through 4F are exemplary, and not intended to limit the scope of the invention. Those skilled in the art will recognize the possibility of using various methods to achieve the structure shown in FIG. 4F.

In FIG. 4D, a third patterned mask layer 413 is formed overlying the base embryo 420, pad embryo 430, second insulating material 452, and further the optional pad embryo 440. The third patterned mask layer 413 comprises an opening 413a exposing the base embryo 420, opening 413b exposing the pad embryo 430, and optional opening 413c exposing the optional pad embryo 440.

In FIG. 4E, the base embryo 420 and pad embryo 430 are thickened by electroplating, electroless plating, or other methods. The optional pad embryo 440 may be thickened simultaneously. Materials for thickening the base embryo 420, pad embryo 430, and optional pad embryo 440 are preferably substantially the same as the conductive substrate 400, such as copper.

The third patterned mask layer 413 is then removed as shown in FIG. 4F.

A dielectric material 462 is formed by use of the base embryo 420, pad embryo 430, and optional pad embryo 440 as a mask as shown in FIG. 4G. The dielectric material 462 covers at least the wiring 461 and may further cover the second insulating material 452. Put simply, the dielectric material 462 is disposed between the base embryo 420 and pad embryo 430 and further between the base 420 and optional pad embryo 440.

A conductive layer 475 is formed overlying the base embryo 420, pad embryo 430, at least parts of the dielectric material 462, and further the optional pad embryo 440 as shown in FIGS. 4H through 4J. The combined conductive layer 475 and base embryo 420 form a base 425. The combined conductive layer 475 and pad embryo 430 form a pad 435. The combined conductive layer 475 and optional pad embryo 440 form an optional pad 445. The conductive layer 475 overlying at least parts of the dielectric layer 462 acts as a trace line 480. Note that the steps shown in FIGS. 4H through 4J are exemplary, and not intended to limit the scope of the invention. Those skilled in the art will recognize the possibility of using various methods to achieve the structure shown in FIG. 4J.

In FIG. 4H, a fourth patterned mask layer 414 is formed overlying the base embryo 420, pad embryo 430, at least parts of the dielectric material 462, and further the optional pad embryo 440. The fourth patterned mask layer 414 comprises an opening 414a exposing the base embryo 420, opening 414b exposing the pad embryo 430, opening 414d exposing at least parts of the dielectric material 462, and optional opening 414c exposing the optional pad embryo 440.

In FIG. 4I, the conductive layer 475 is formed by electroplating, electroless plating, or other methods. Thus, the base 425, pad 435, trace line 480, and optional pad 445 are formed as described. The trace line 480 is disposed beyond the base 425, and the pad 435 is disposed beyond the trace line 480. The conductive layer 475 is preferably substantially the same material as the conductive substrate 400, such as copper.

At least parts of the dielectric material 462 is disposed between at least parts of the trace line 480 and a part 461a of the wiring 461 to be an embedded capacitor, wherein the trace lines 480 and part 461a act as electrodes thereof.

The fourth patterned mask layer 414 is then removed as shown in FIG. 4J.

In FIG. 4K, a third insulating material 453 is formed overlying the dielectric material 462 by use of the base 425, pad 435, optional pad 445, and trace line 480 as a mask. Put simply, the third insulating material 453 is disposed between the base 425, trace line 480, and pad 435, and further between the base 425 and optional pad 445.

In FIG. 4L, at least the conductive substrate 400 underlying the first insulating material 451 is removed. In this embodiment, the conductive substrate 400 is completely removed by etching or grounding. Details regarding a method removing the conductive substrate 400 underlying the first insulating material 451 only are the same as those described for FIGS. 2A through 2E, and thus, are omitted in the following.

A solder mask 490 as shown in FIG. 4M is optionally formed overlying the trace line 480, pad 435, and/or optional pad 445 as required by use of a method such as stencil printing.

In the following eighth embodiment, another method for fabricating the leadframes of the sixth embodiment of the invention is disclosed.

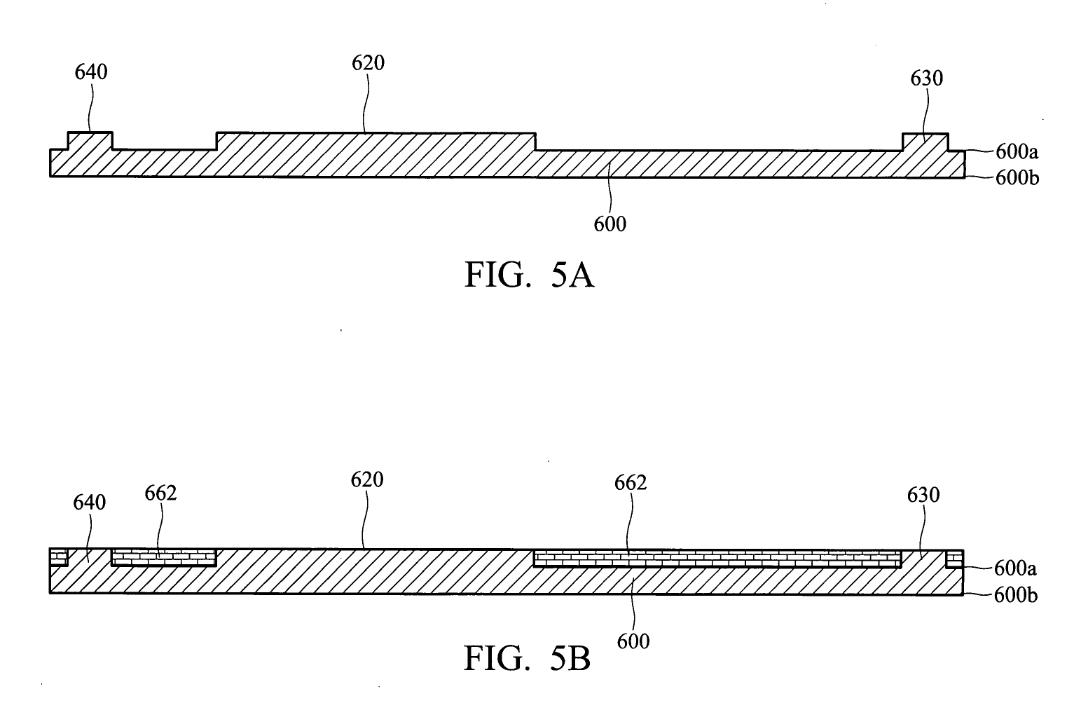

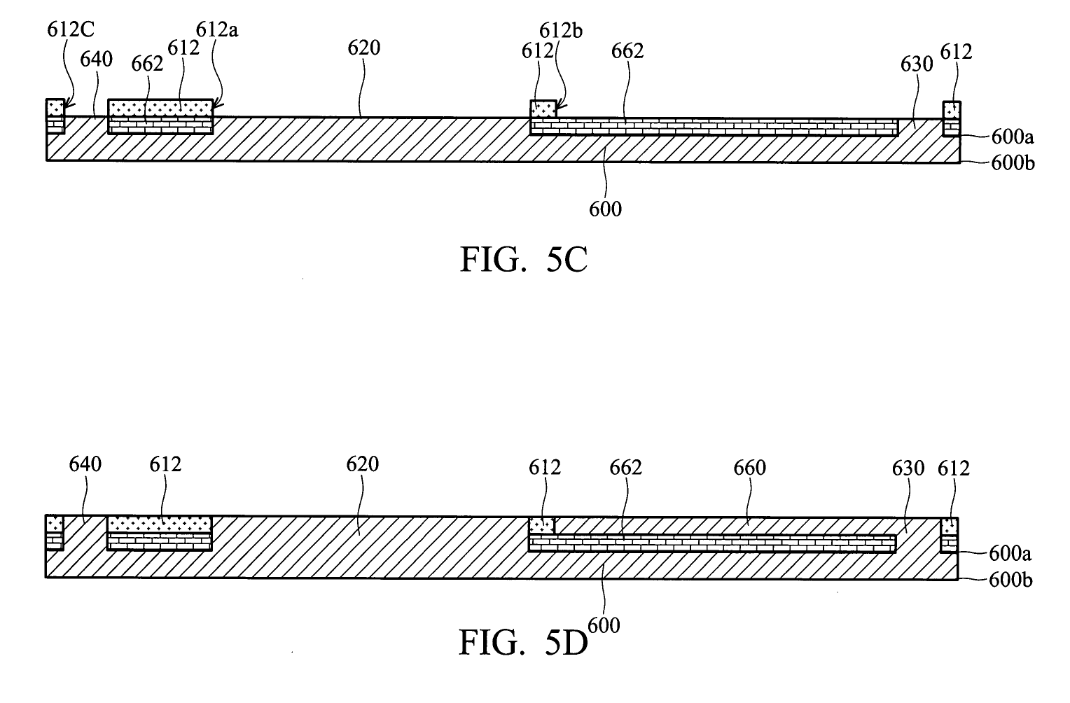

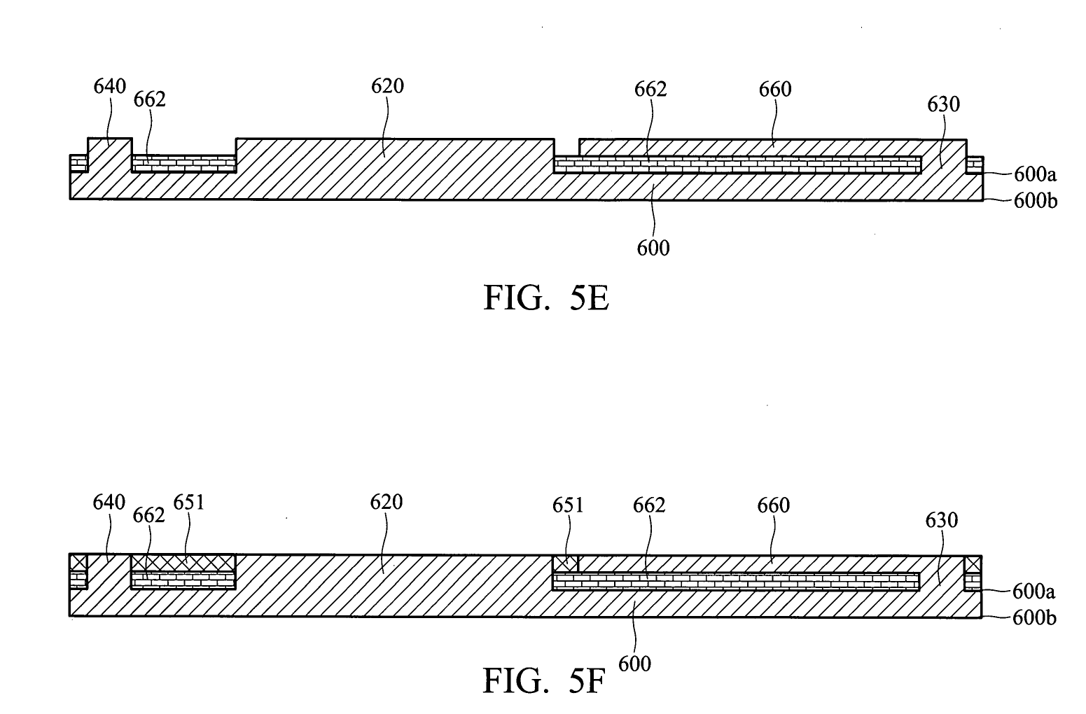

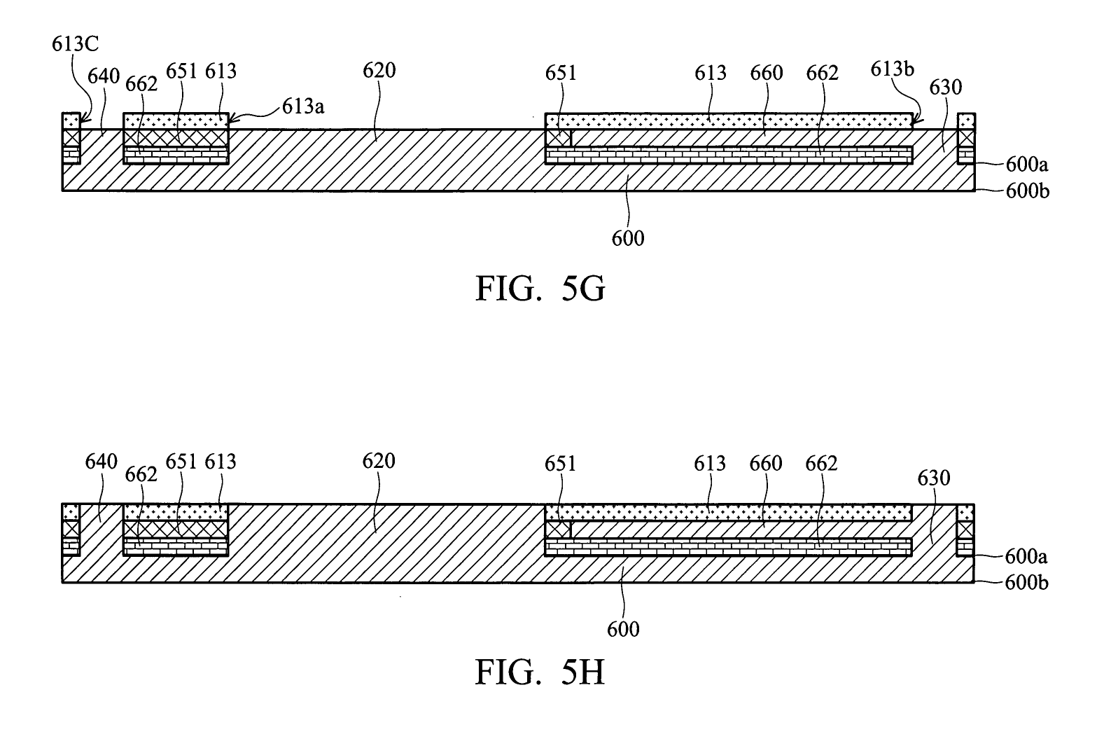

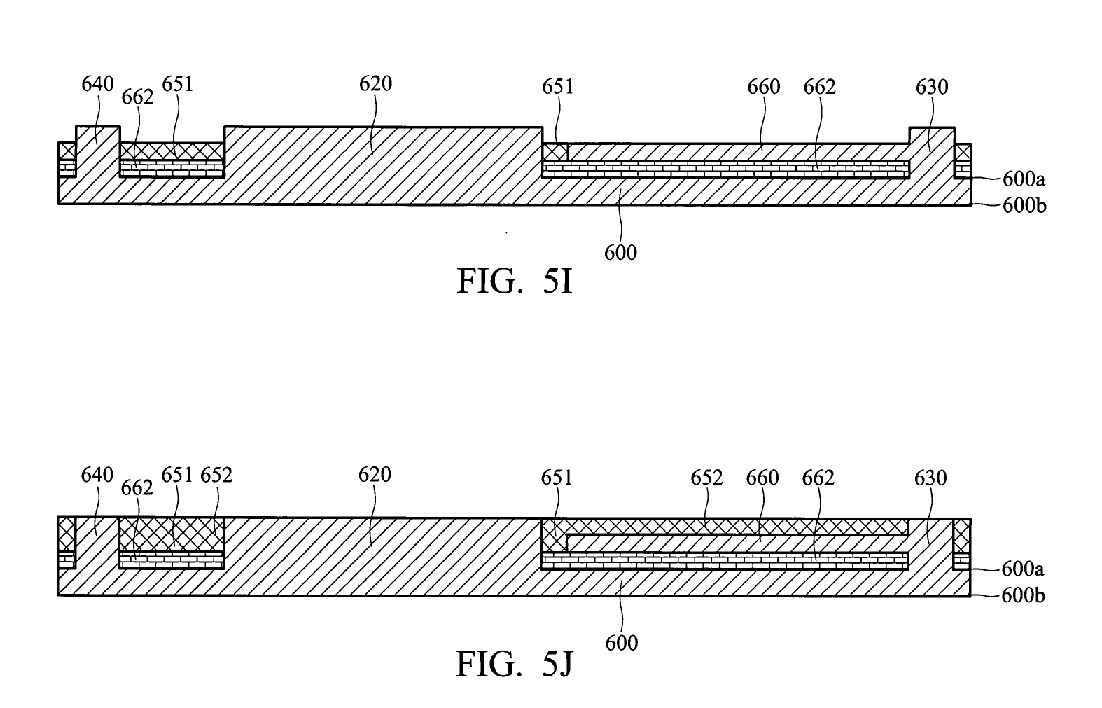

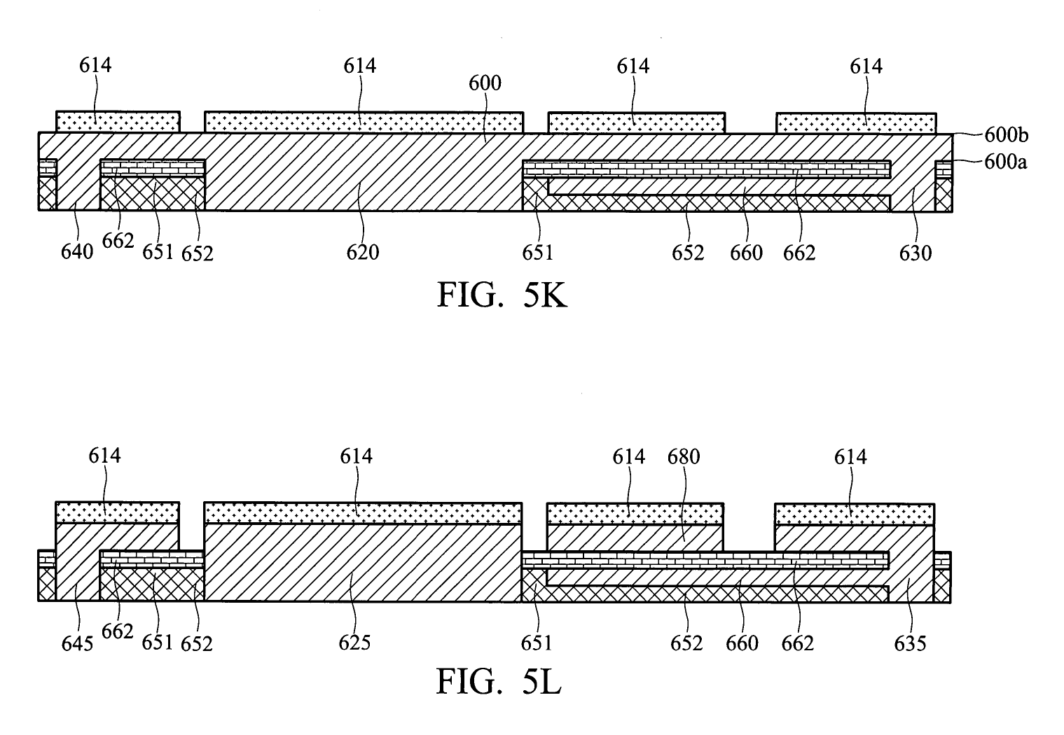

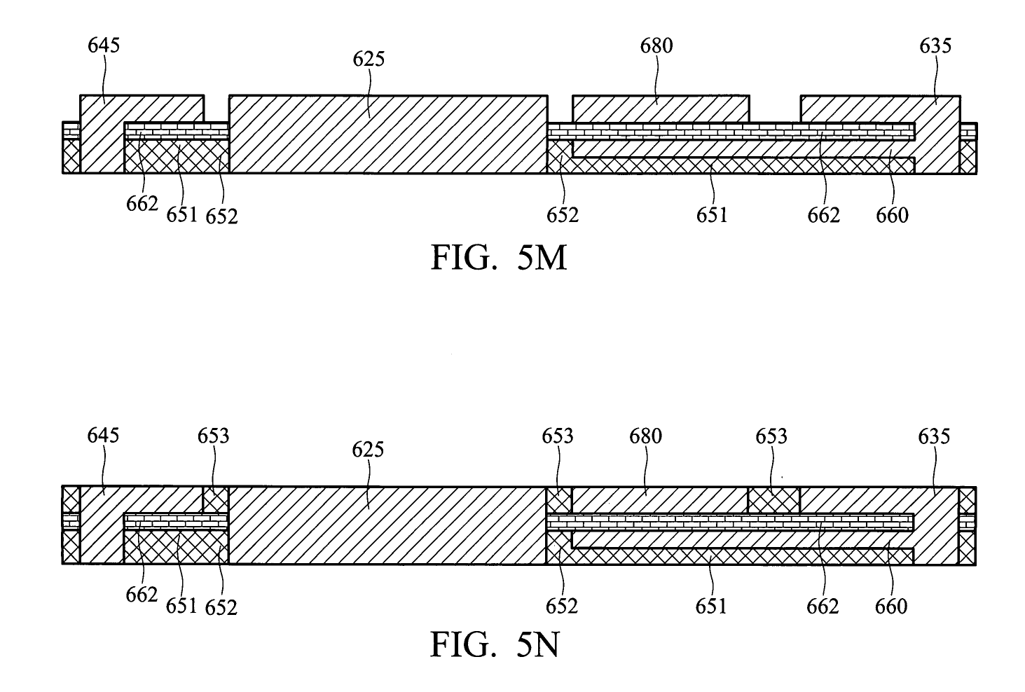

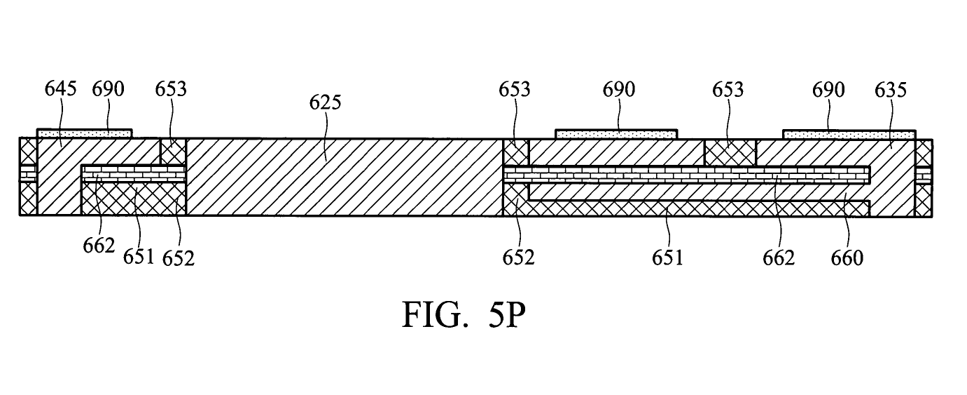

In FIGS. 5A through 5N and 5P, cross-sections of a method for fabricating the leadframes of the sixth embodiment of the invention are shown.

In FIG. 5A, a conductive substrate 600, preferably copper, is provided. The conductive substrate 600 comprises a top surface 600a and bottom surface 600b. Details regarding the base embryo 620, pad embryo 630, and optional pad embryo 640 are the same as the respective base embryo 125, pad embryo 135, and optional pad embryo 145 described for FIG. 1D, and thus, are omitted in the following.

In FIG. 5B, a dielectric material 662 is formed overlying the top surface 600a of the conductive substrate 600 by use of the base embryo 620, pad embryo 630, and optional pad embryo 640 as a mask.

The base embryo 620, pad embryo 630, and further the optional pad embryo 640 are thickened, and a wiring 660 electrically connecting the pad embryo 630 is formed as shown in FIGS. 5C through 5E. Note that the steps shown in FIGS. 5C through 5E are exemplary, and not intended to limit the scope of the invention. Those skilled in the art will recognize the possibility of using various methods to achieve the structure shown in FIG. 5E.

In FIG. 5C, a second patterned mask layer 612 is formed overlying the base embryo 620, pad embryo 630, dielectric material 662, and further the optional pad embryo 640. The second patterned mask layer 612 comprises an opening 612a exposing the base embryo 620, opening 612b exposing the pad embryo 230 and a predetermined region for the wiring 660, and optional opening 612c exposing the optional pad embryo 640.

In FIG. 5D, the base embryo 620 and pad embryo 630 are thickened, and the wiring 660, electrically connecting the pad embryo 630, is simultaneously formed in the opening 612b (shown in FIG. 5C) by electroplating, electroless plating, or other methods. The optional pad embryo 640 may be thickened simultaneously. The wiring 660 is disposed beyond the base embryo 620. The wiring 660 may further comprise a passive component 261 (not shown), such as a resistor, inductor, capacitor, or combinations thereof.

The wiring 660 and materials thickening the base embryo 620, pad embryo 630, and optional pad embryo 640 are preferably substantially the same as the conductive substrate 600, such as copper.

The second patterned mask layer 612 is then removed as shown in FIG. 5E.

In FIG. 5F, a first insulating material 651 is formed overlying the dielectric material 662 by use of the base embryo 620, pad embryo 630, optional pad embryo 640, and wiring 660 as a mask. Put simply, the first insulating material 651 is disposed between the base embryo 620 and wiring 660, and further between the base 620 and optional pad embryo 640.

The base embryo 620, pad embryo 630, and the optional pad embryo 640 are thickened as shown in FIGS. 5G through 5I. Note that the steps shown in FIGS. 5G through 5I are exemplary, and not intended to limit the scope of the invention. Those skilled in the art will recognize the possibility of using various methods to achieve the structure shown in FIG. 5I.

In FIG. 5G, a third patterned mask layer 613 is formed overlying the base embryo 620, pad embryo 630, first insulating material 651, and further the optional pad embryo 640. The third patterned mask layer 613 comprises an opening 613a exposing the base embryo 620, opening 613b exposing the pad embryo 630, and optional opening 613c exposing the optional pad embryo 640.

In FIG. 5H, the base embryo 620 and pad embryo 630 are thickened by electroplating, electroless plating, or other methods. The optional pad embryo 640 may be thickened simultaneously. Materials thickening the base embryo 620, pad embryo 630, and optional pad embryo 640 are preferably substantially the same as the conductive substrate 600, such as copper.

The third patterned mask layer 613 is then removed as shown in FIG. 5I.

In FIG. 5J, a second insulating material 652 is formed covering the wiring 660 and the first insulating material 651 by use of the base embryo 620, pad embryo 630, and optional pad embryo 640 as a mask. Put simply, the third insulating material 653 is disposed between the base embryo 620 and pad embryo 630 and further between the base 620 and optional pad embryo 640.

Following FIG. 5J, the structures shown in subsequent figures are flipped as compared thereto.

Parts of the conductive substrate 600 are removed, resulting in combination of the base embryo 620 and the underlying conductive substrate 600 serving as a base 625, formation of a trace line 680 beyond the base 625, and combination of the pad embryo 630 and the underlying conductive substrate 600 being a pad 635 as shown in FIGS. 5K through 5M. An optional pad 645 may be formed simultaneously resulting from combination of the optional pad embryo 640 and the underlying conductive substrate 600. Note that the steps shown in FIGS. 5K through 5M are exemplary, and not intended to limit the scope of the invention. Those skilled in the art will recognize the possibility of using various methods to achieve the structure shown in FIG. 5M.

In FIG. 5K, a fourth patterned mask layer 614 is formed underlying the bottom surface 600b of the conductive substrate 600, covering the conductive substrate 600 underlying the respective base embryo 620, pad embryo 630, dielectric material 662, and the optional pad embryo 640.

In FIG. 5L, the conductive substrate 600 not covered by the fourth patterned mask layer 614 is removed by a method such as etching to form the base 625, pad 635, and optional pad 645 as described. Further, the remaining conductive substrate 600 underlying the dielectric material 662 becomes the trace line 680. The trace line 680 is disposed beyond the base 625, the pad 635 is disposed beyond the trace line 680, and the optional pad 645 is disposed beyond the base 625.

At least parts of the dielectric material 662 are disposed between at least parts of the trace line 680 and at least parts of the wiring 660 to serve as an embedded capacitor, wherein the trace lines 680 and wiring 660 act as electrodes thereof.

The fourth patterned mask layer 614 is then removed as shown in FIG. 5M.

In FIG. 5N, a third insulating material 653 is formed covering the dielectric material 662 by use of the base 625, pad 635, optional pad 645, and trace line 680 as a mask. Put simply, the third insulating material 653 is disposed between the base 625, trace line 680, and pad 635, and further between the base 625 and optional pad 645.

In FIG. 5P, a solder mask 690 is optionally formed overlying the trace line 680, pad 635, and/or optional pad 645 as required by use of a method such as stencil printing.

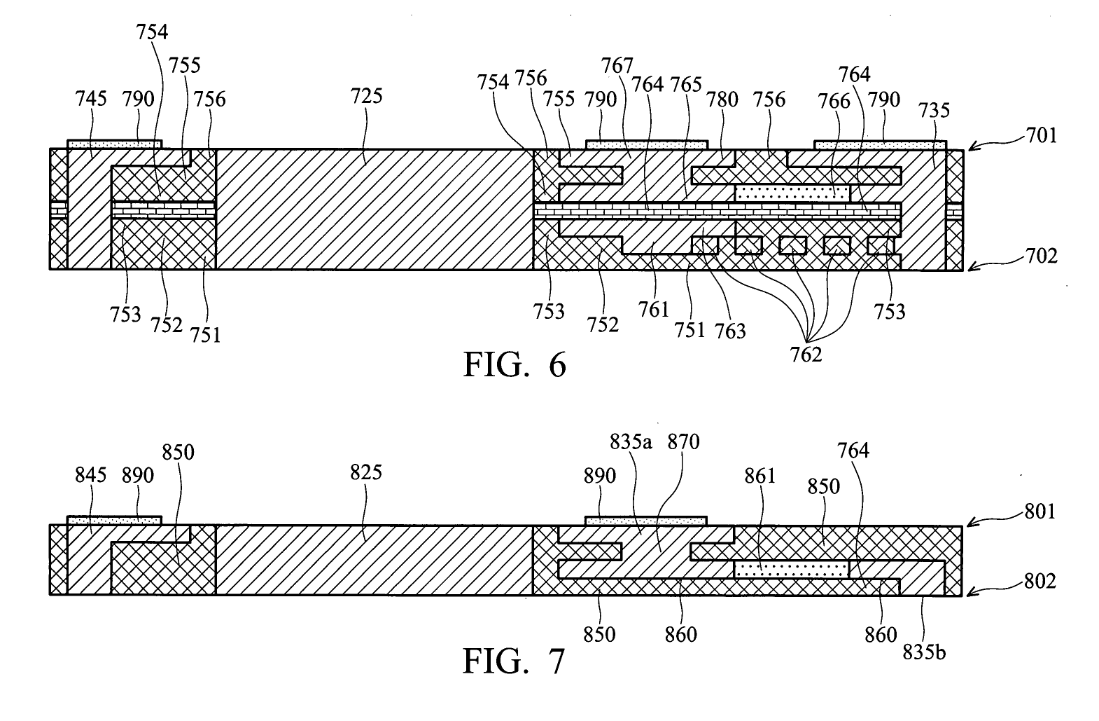

FIG. 6 shows a cross-section of a leadframe with an embedded passive component of a ninth embodiment of the invention. Details regarding the first surface 701, second surface 702, base 725, pad 735, optional pad 745, first insulating material 751, sixth insulating material 756, trace line 780, and solder mask 790 are the same as the respective first surface 101, second surface 102, base 125, pad 135, optional pad 145, first insulating material 151, fourth insulating material 154, trace line 180, and solder mask 190 described for FIG. 1U, and thus, are omitted in the following.

In this embodiment, the leadframe comprises a multi-layered wiring as described below.

In FIG. 6, a first wiring 761 is formed overlying the first insulating material 751, electrically connecting the pad 735. A second insulating material 752 is disposed between the base 725 and first wiring 761. The first wiring 761 comprises a passive component 762, such as an inductor.

A parallel electrode 763 is formed overlying the first wiring 761 and electrically connected thereto. A third insulating material 753 is disposed between the base 725, parallel electrode 763, and pad 735.

A dielectric material 764 is formed overlying the parallel electrode 763 and third insulating material 753, disposed between the base 725 and pad 735, and optionally between the base 725 and optional pad 745. At least parts of the dielectric material 764 is being a dielectric of an embedded capacitor.

A second wiring 765 is formed overlying the dielectric material 764, electrically connecting the pad 735. A fourth insulating material 754 is disposed between the base 725 and second wiring 765. At least parts of the second wiring 765 corresponds to the neighboring dielectric material 764 and parallel electrode 763, resulting in formation of an embedded capacitor comprised thereof. The second wiring 762 may further comprise a passive component 766, such as a resistor.

An electrical connection layer 767 electrically connects the trace line 780 and second wiring 765. A fifth insulating material 755 is disposed between the base 725, electrical connection layer 767, pad 735.

Methods for fabricating the leadframe of this embodiment are achieved by combinations of steps described in FIGS. 1A through 1V, 2A through 2E, 3A through 3T, 4A through 4M, and 5A through 5P, and are thus, omitted in the following.

In FIG. 7, a cross-section of a leadframe with an embedded passive component of a tenth embodiment of the invention is shown. The leadframe comprises opposite first surface 801 and second surface 802. The leadframe comprises opposite first surface 101 and second surface 102. In this embodiment, the leadframe comprises a base 825, first pad 835a, second pad 835b, wiring 860, and insulating materials 850.

The base 825 is exposed in the first surface 801 and second surface 802. An active device (not shown), such as a semiconductor chip, photoelectric device, or other devices, is attached to the base 825 in a packaging process.

The first pad 835a, exposed in the first surface 801, is disposed beyond the base 825. A solder mask 890 is optionally formed overlying the first pad 835a. In the packaging process, the first pad 835a acts as an electrode. The active device may attach to the first pad 835a, electrically connecting the leadframe using a method such as wire bonding, flip chip, or other methods.

The second pad 835b, exposed in the second surface 802, is disposed beyond the base 825. When the packaging process is finished, the second pad 835b acts as an electrode of a package to electrically connect an external device.

The wiring 860, comprising a passive component 860a, is disposed between the first and second surfaces 801, 802. The wiring 860 electrically connects the respective first and second pads 835a, 835b. The wiring 860 can be single-layered or multi-layered. The passive component 860a comprises a resistor, inductor, capacitor, or combinations thereof. In this embodiment, the wiring 860 is single-layered, and the passive component 860a is a resistor. An electrical connection layer 870 may be optionally disposed between the wiring 860 and first pad 835 to form their electrical connection.

An insulating material 850 is disposed among the base 825, first pad 835a, second pad 835b, and wiring 860, and substantially covers the wiring 860. The insulating material 850 prevents the respective first pad 835a, second pad 835b, and wiring 860 from electrical connection to the base 825.

The leadframe may further comprise an optional third pad 845, exposed in the first and second surfaces 801 and 802 and disposed beyond the base 825. The insulating material 850 may be disposed between the base 825 and third pad 845 to provide electrical insulation therebetween. The solder mask 890 may be optionally disposed overlying the third pad 845.

The base 825, first pad 835a, second pad 835b, third pad 845, electrical connection layer 870, wiring 860, and the passive component 860a are preferably metal, and more preferably copper or copper alloys. As described, the passive component 860a is a resistor, and an example thereof is shown in FIG. 11.

In the following eleventh embodiment, a modification of the leadframe of the tenth embodiment of the invention is disclosed.

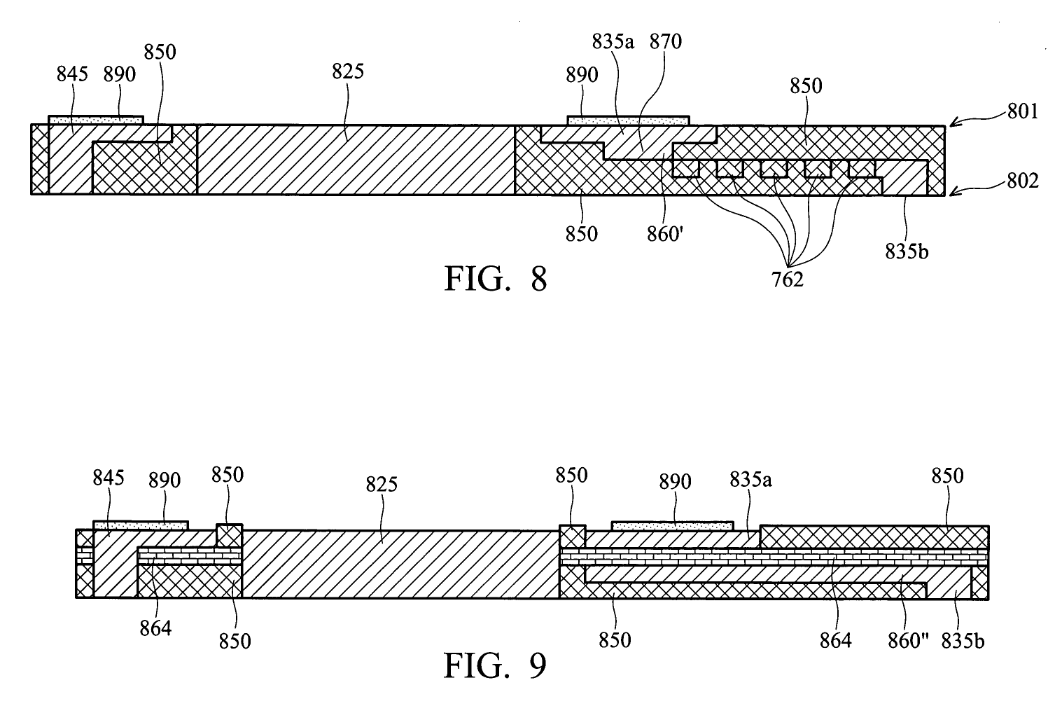

A wiring 860′ comprising a passive component 862 replaces the wiring 860 of the leadframe of the tenth embodiment, as shown in FIG. 8, a cross-section of a leadframe with an embedded passive component of an eleventh embodiment of the invention. Details regarding the other elements are the same as those described for FIG. 7, and thus, are omitted in the following.

In this embodiment, the passive component 862 is an inductor, the three exemplary three-dimensional skeleton diagrams of which are shown in FIGS. 12A through 12C. The passive component 862 is substantially as thick as the neighboring wiring 860′, but extends more circuitously as required to be an inductor. Further, the wiring 860′ and passive component 862 are preferably metal, and more preferably copper or copper alloys.

In the following twelfth embodiment, another modification of the leadframe of the tenth embodiment of the invention is disclosed.

A wiring 860″ replaces the wiring 860 of the leadframe of the tenth embodiment, as shown in FIG. 9, a cross-section of a leadframe with an embedded passive component of a twelfth embodiment of the invention. A dielectric material 864 is further disposed between at least parts of the wiring 860″ and at least parts of the first pad 835a. Details regarding the other elements are the same as those described for FIG. 7, and thus, are omitted in the following.

In this embodiment, the wiring 860″, electrically connecting the second pad 835b, is disposed underlying the first pad 835a. Thus, an embedded capacitor comprising at least parts of the wiring 860″, at least parts of the first pad 835a, and the dielectric material 864 therebetween is formed.

Moreover, the wiring 860″ may further comprise a passive component, such as an inductor, resistor, another capacitor, or combinations thereof but is not shown.

When the wiring 860 shown in FIG. 7 is multi-layered, the multi-layered wiring is described in detail as the following thirteenth embodiment.

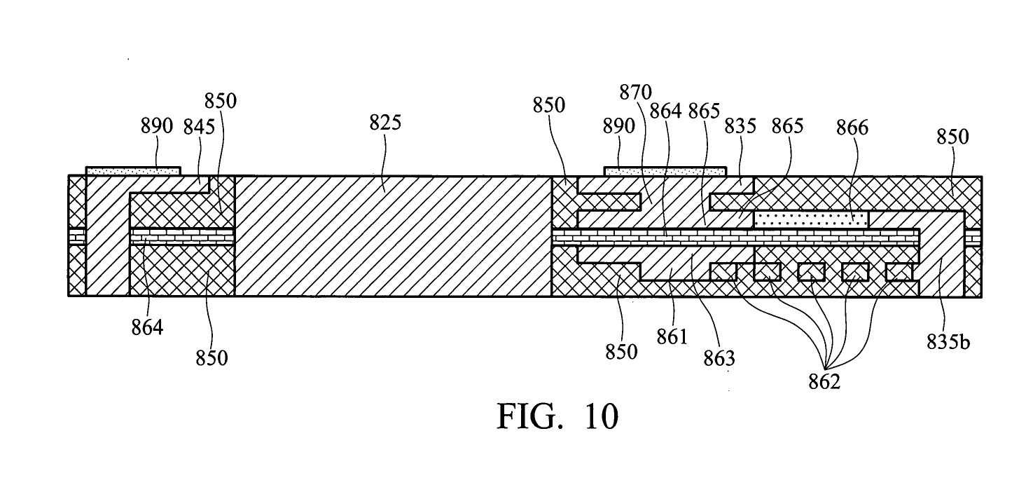

A multi-layered wiring and a dielectric material replace the wiring 860 of the leadframe of the tenth embodiment, as shown in FIG. 10, a cross-section of a leadframe with an embedded passive component of a thirteenth embodiment of the invention. Details regarding other elements are the same as those described for FIG. 7, and thus, are omitted in the following.

In FIG. 10, a first wiring 861, electrically connecting the second pad 835b, is covered by the insulating material 850. The insulating material 850 is further disposed between the base 825 and the first wiring 861.

A parallel electrode 863 is disposed overlying the first wiring 861 and electrically connected thereto. The insulating material 850 is further disposed between the base 825, parallel electrode 863, and the second pad 835b.

The dielectric material 864, disposed overlying the parallel electrode 863, is between the base 825 and second pad 835b, and optionally between the base 825 and pad 845. At least parts of the dielectric material 864 are the dielectric layer of an embedded capacitor.

A second wiring 865, electrically connecting the second pad 835b, is disposed overlying the dielectric material 864. The insulating material 850 is also disposed between the base 825 and second wiring 865. At least parts of the second wiring 865 corresponds to the neighboring dielectric material 864 and parallel electrode 863, resulting in formation of an embedded capacitor comprised thereof. The second wiring 865 may further comprise a passive component 866, such as a resistor.

An electrical connection layer 870 electrically connects the first pad 835a and second wiring 865. The insulating material 850 is disposed between the base 825, and electrical connection layer 870.

Methods for fabricating the leadframes of the tenth through thirteen embodiments of the invention are achieved by combinations and modifications of descriptions for FIGS. 1A through 1V, 2A through 2E, 3A through 3T, 4A through 4M, and 5A through 5P, and thus, are omitted in the following.

Thus, the results show the efficacy of the inventive leadframe module with an embedded passive component, resulting in reducting the total aspect compared to the conventional package and passive device, reducing the connection pace therebetween to improve to electrical performance, capable of reduction of the wiring density and aspect of an external device, such as a PCB, subsequently connecting thereto to improve the entire electrical performance of an end product, thereby achieving the described aims of the invention.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

1. A multilayer leadframe module with an embedded passive component comprising opposite first and second surfaces, comprising:
a base exposed in the first and second surfaces;
a trace line, exposed in the first surface, beyond the base;
a pad, exposed in at least the second surface, beyond the trace line;
a wiring, comprising a passive component and respectively electrically connecting the trace line and pad, disposed between the first and second surfaces; and
an insulating material among the base, trace line, pad, and wiring, and substantially covering the wiring.

2. The module as claimed in claim 1, wherein the pad is further exposed in the first surface.

3. The module as claimed in claim 2, further comprising a solder mask overlying the pad exposed in the first surface.

4. The module as claimed in claim 1, further comprising a solder mask overlying the trace line.

5. The module as claimed in claim 1, wherein the wiring is single-layered or multi-layered.

6. The module as claimed in claim 1, wherein the passive component comprises a resistor, inductor, capacitor, or combinations thereof.

7. A multilayer leadframe module with an embedded passive component comprising opposite first and second surfaces, comprising:
a base exposed in the first and second surfaces;
a trace line, exposed in the first surface, beyond the base;
a first pad, exposed in the first and second surfaces, beyond the trace line;
a wiring, electrically connecting the first pad, underlying the trace line;
a dielectric material between at least parts of the trace line and at least parts of the wiring, thereby forming an embedded capacitor comprising the trace line, dielectric material, and wiring; and
an insulating material between the base and trace line, and between the trace line and first pad, and extending to the second surface to substantially cover the wiring.

8. The module as claimed in claim 7, further comprising a second pad, exposed in the first and second surfaces, beyond the base, wherein the insulating material is further disposed between the base and second pad.

9. The module as claimed in claim 7, further comprising a solder mask overlying the first pad exposed in the first surface.

10. The module as claimed in claim 7, further comprising a solder mask overlying the trace line.

11. The module as claimed in claim 8, further comprising a solder mask overlying the second pad exposed in the first surface.

12. The module as claimed in claim 7, wherein the wiring is single-layered or multi-layered.

13. The module as claimed in claim 7, wherein the wiring further comprises a passive component beyond the embedded capacitor.

14. The module as claimed in claim 13, wherein the passive component comprises a resistor, inductor, another capacitor, or combinations thereof.

15. A method for fabricating a leadframe module with an embedded passive component, comprising:
providing a conductive substrate comprising a top surface and bottom surface;
forming a base embryo and pad embryo beyond the base embryo overlying parts of the top surface of the conductive substrate;
forming a first insulating material overlying the top surface of the conductive substrate beyond the base embryo and pad embryo;
thickening the base embryo and pad embryo, and forming a wiring, comprising a passive component and electrically connecting the pad embryo, beyond the base embryo;
forming a second insulating material overlying the first insulating material beyond the base embryo, pad embryo, and wiring;
thickening the base embryo and pad embryo, and forming an electrical connection layer overlying at least parts of the wiring;
forming a third insulating material covering the second insulating material and wiring;
thickening the base embryo and pad embryo to serve as a base and pad respectively, and forming a trace line overlying the electrical connection layer, wherein the trace line is disposed beyond the base, and the pad is disposed beyond the trace line;
forming a fourth insulating material overlying the third insulating material and electrical connection layer beyond the base, pad, and trace line; and
removing the conductive substrate at least underlying the first insulating material.

16. The method as claimed in claim 15, further comprising completely removing the conductive substrate.

17. The method as claimed in claim 15, further comprising:
removing the conductive substrate underlying the first insulating material, wherein the remaining parts of the conductive substrate respectively serve as parts of the base and pad respectively; and
forming a fifth insulating material underlying the first insulating material.

18. The method as claimed in claim 15, further comprising forming a solder mask overlying the trace line and pad.

19. The method as claimed in claim 15, wherein the conductive substrate, base, trace line, and pad comprise copper.

20. The method as claimed in claim 15, wherein the wiring is single-layered or multi-layered.

21. The method as claimed in claim 15, wherein the passive component comprises a resistor, inductor, capacitor, or combinations thereof.

22. The method as claimed in claim 15, wherein forming the base embryo and pad embryo further comprises:
forming a first patterned mask layer overlying the top surface of the conductive substrate, exposing predetermined regions of the top surface for the base and pad;
forming the base embryo and pad embryo overlying the exposed top surface of the conductive substrate; and
removing the first patterned mask layer.

23. The method as claimed in claim 15, wherein thickening the base embryo and pad embryo, and forming the wiring further comprise:
forming a second patterned mask layer overlying the base embryo, pad embryo, and first insulating material, exposing the base embryo, pad embryo, and a predetermined region for the wiring;
thickening the base embryo and pad embryo, and forming the wiring electrically connecting the pad embryo; and
removing the second patterned mask layer.

24. The method as claimed in claim 15, wherein thickening the base embryo and pad embryo, and forming the electrical connection layer further comprise:
forming a third patterned mask layer overlying the base embryo, pad embryo, wiring, and second insulating material, exposing the base embryo, pad embryo, and at least parts of the wiring;
thickening the base embryo and pad embryo, and forming the electrical connection layer overlying the exposed wiring; and
removing the third patterned mask layer.

25. The method as claimed in claim 15, wherein thickening the base embryo and pad embryo, and forming the trace line further comprise:
forming a fourth patterned mask layer overlying the base embryo, pad embryo, electrical connection layer, and the third insulating material, exposing the base embryo, pad embryo, and electrical connection layer;
thickening the base embryo and pad embryo, and forming the trace line overlying the exposed electrical connection layer; and
removing the fourth patterned mask layer.

26. The method as claimed in claim 17, wherein removing the conductive substrate underlying the first insulating material further comprises:
forming a fifth patterned mask layer underlying the bottom surface of the conductive substrate, exposing the conductive substrate underlying the first insulating material;
removing the exposed conductive substrate; and
removing the fifth patterned mask layer.

27. A method for fabricating a leadframe module with an embedded passive component, comprising:
providing a conductive substrate comprising a top surface and bottom surface;
forming a base embryo, electrical connection layer beyond the base embryo, and pad embryo beyond the electrical connection layer overlying the top surface of the conductive substrate;
forming a first insulating material overlying the top surface of the conductive substrate beyond the base embryo, electrical connection layer, and pad embryo;
thickening the base embryo and pad embryo, and forming a wiring, comprising a passive component and electrically connecting the respective pad embryo and electrical connection layer, beyond the base embryo;
forming a second insulating material overlying the first insulating material beyond the base embryo, pad embryo, and wiring;
thickening the base embryo and pad embryo;
forming a third insulating material overlying the wiring and second insulating material beyond the base embryo and pad embryo;
removing parts of the conductive substrate, resulting in combination of the base embryo and the underlying conductive substrate serving as a base, formation of a trace line electrically connecting to the wiring via the electrical connection layer, and combination of the pad embryo and the underlying conductive substrate serving as a pad, wherein the trace line is disposed beyond the base, and the pad is disposed beyond the trace line; and
forming a fourth insulating material in positions left by the removed conductive substrate.

28. The method as claimed in claim 27, further comprising forming a solder mask overlying the trace line and pad.

29. The method as claimed in claim 27, wherein the conductive substrate, base, trace line, and pad comprise cooper.

30. The method as claimed in claim 27, wherein the wiring is single-layered or multi-layered.

31. The method as claimed in claim 27, wherein the passive component comprises a resistor, inductor, capacitor, or combinations thereof.

32. The method as claimed in claim 27, wherein forming the base embryo, electrical connection layer, and pad embryo further comprises:
forming a first patterned mask overlying the top surface of the conductive substrate, exposing predetermined regions of the top surface for the base, electrical connection layer, and pad;
forming the base embryo, electrical connection layer, and pad embryo overlying the exposed top surface of the conductive substrate; and
removing the first patterned mask.

33. The method as claimed in claim 27, wherein thickening the base embryo and pad embryo, and forming the wiring further comprise:
forming a second patterned mask layer overlying the base embryo, electrical connection layer, pad embryo, and first insulating material, exposing the base embryo, pad embryo, and a predetermined region for the wiring;
thickening the base embryo and pad embryo, and forming the wiring; and
removing the second patterned mask layer.

34. The method as claimed in claim 27, wherein thickening the base embryo and pad embryo further comprises:
forming a third patterned mask layer overlying the base embryo, pad embryo, and second insulating material, exposing the base embryo and pad embryo;
thickening the base embryo and pad embryo; and
removing the third patterned mask layer.

35. The method as claimed in claim 27, wherein removing parts of the conductive substrate further comprises:
forming a fourth patterned mask layer underlying the bottom surface of the conductive substrate, respectively covering the conductive substrate underlying the base embryo, electrical connection layer, and pad embryo;
removing the conductive substrate not covered by the fourth patterned mask layer; and
removing the fourth patterned mask layer.

36. A method for fabricating a leadframe module with an embedded passive component, comprising:
providing a conductive substrate comprising a top surface and bottom surface;
forming a base embryo and pad embryo beyond the base embryo overlying parts of the top surface of the conductive substrate;
forming a first insulating material overlying the top surface of the conductive substrate beyond the base embryo and pad embryo;
thickening the base embryo and pad embryo, and forming a wiring, electrically connecting the pad embryo, beyond the base embryo;
forming a second insulating material overlying the first insulating material beyond the base embryo, pad embryo, and wiring;
thickening the base embryo and pad embryo;
forming a dielectric material at least overlying the wiring;
thickening the base embryo and pad embryo to serve as a base and pad respectively, and forming a trace line overlying at least parts of the dielectric material, wherein the trace line is disposed beyond the base, and the pad is disposed beyond the trace line, resulting in at least parts of the dielectric material disposed between at least parts of the trace line and at least parts of the wiring serving as an embedded capacitor;
forming a third insulating material overlying the dielectric material beyond the base, pad, and trace line; and
removing the conductive substrate at least underlying the first insulating material.

37. The method as claimed in claim 36, further comprising completely removing the conductive substrate.

38. The method as claimed in claim 36, further comprising:
removing the conductive substrate underlying the first insulating material, wherein the remaining parts of the conductive substrate respectively serving as parts of the base and pad respectively; and
forming a fifth insulating material underlying the first insulating material.

39. The method as claimed in claim 36, further comprising forming a solder mask overlying the trace line and pad.

40. The method as claimed in claim 36, wherein the conductive substrate, base, trace line, and pad comprise copper.

41. The method as claimed in claim 36, wherein the wiring is single-layered or multi-layered.

42. The method as claimed in claim 36, wherein the wiring further comprises a passive component.

43. The method as claimed in claim 42, wherein the passive component comprises a resistor, inductor, another capacitor, or combinations thereof.

44. The method as claimed in claim 36, wherein forming the base embryo and pad embryo further comprises:
forming a first patterned mask layer overlying the top surface of the conductive substrate, exposing predetermined regions of the top surface for the base and pad;
forming the base embryo and pad embryo overlying the exposed top surface of the conductive substrate; and
removing the first patterned mask layer.

45. The method as claimed in claim 36, wherein thickening the base embryo and pad embryo, and forming the wiring further comprise:
forming a second patterned mask layer overlying the base embryo, pad embryo, and first insulating material, exposing the base embryo, pad embryo, and a predetermined region for the wiring;
thickening the base embryo and pad embryo, and forming the wiring electrically connecting the pad embryo; and
removing the second patterned mask layer.

46. The method as claimed in claim 36, wherein thickening the base embryo and pad embryo further comprises:
forming a third patterned mask layer overlying the base embryo, pad embryo, wiring, and second insulating material, exposing the base embryo and pad embryo;
thickening the base embryo and pad embryo; and
removing the third patterned mask layer.

47. The method as claimed in claim 36, wherein thickening the base embryo and pad embryo, and forming the trace line further comprise:
forming a fourth patterned mask layer overlying the base embryo, pad embryo, and the dielectric material, exposing the base embryo, pad embryo, and at least the dielectric material overlying the wiring;
thickening the base embryo and pad embryo, and forming the trace line overlying the exposed dielectric material; and
removing the fourth patterned mask layer.

48. The method as claimed in claim 38, wherein removing the conductive substrate underlying the first insulating material further comprises:
forming a fifth patterned mask layer underlying the bottom surface of the conductive substrate, exposing the conductive substrate underlying the first insulating material;
removing the exposed conductive substrate; and
removing the fifth patterned mask layer.

49. A method for fabricating a leadframe module with an embedded passive component, comprising:
providing a conductive substrate comprising a top surface and bottom surface;
forming a base embryo and pad embryo beyond the base embryo overlying the top surface of the conductive substrate;
forming a dielectric material overlying the top surface of the conductive substrate beyond the base embryo and pad embryo;
thickening the base embryo and pad embryo, and forming a wiring, electrically connecting the pad embryo, beyond the base embryo;
forming a first insulating material overlying the dielectric material beyond the base embryo, pad embryo, and wiring;
thickening the base embryo and pad embryo;
forming a second insulating material overlying the wiring and second insulating material beyond the base embryo and pad embryo;
removing parts of the conductive substrate, resulting in combination of the base embryo and its underlying conductive substrate serving as a base, formation of a trace line, and combination of the pad embryo and its underlying conductive substrate serving as a pad, wherein the trace line is disposed beyond the base, and the pad is disposed beyond the trace line, resulting in at least parts of the dielectric material disposed between at least parts of the trace line and at least parts of the wiring to be an embedded capacitor; and
forming a third insulating material in positions left by the removed conductive substrate.

50. The method as claimed in claim 49, further comprising forming a solder mask overlying the trace line and pad.

51. The method as claimed in claim 49, wherein the conductive substrate, base, trace line, and pad comprise cooper.

52. The method as claimed in claim 49, wherein the wiring is single-layered or multi-layered.

53. The method as claimed in claim 49, wherein the wiring further comprises a passive component.

54. The method as claimed in claim 53, wherein the passive component comprises a resistor, inductor, another capacitor, or combinations thereof.

55. The method as claimed in claim 49, wherein forming the base embryo and pad embryo further comprises:
forming a first patterned mask overlying the top surface of the conductive substrate, exposing predetermined regions of the top surface for the base and pad;
forming the base embryo and pad embryo overlying the exposed top surface of the conductive substrate; and
removing the first patterned mask.

56. The method as claimed in claim 49, wherein thickening the base embryo and pad embryo, and forming the wiring further comprise:
forming a second patterned mask layer overlying the base embryo, pad embryo, and dielectric material, exposing the base embryo, pad embryo, and a predetermined region for the wiring;
thickening the base embryo and pad embryo, and forming the wiring; and
removing the second patterned mask layer.

57. The method as claimed in claim 49, wherein thickening the base embryo and pad embryo further comprises:
forming a third patterned mask layer overlying the base embryo, pad embryo, and first insulating material, exposing the base embryo and pad embryo;
thickening the base embryo and pad embryo; and
removing the third patterned mask layer.

58. The method as claimed in claim 49, wherein removing parts of the conductive substrate further comprises:
forming a fourth patterned mask layer underlying the bottom surface of the conductive substrate, respectively covering the conductive substrate underlying predetermined regions for the base, pad, and trace line;
removing the conductive substrate not covered by the fourth patterned mask layer; and
removing the fourth patterned mask layer.

59. A leadframe module with an embedded passive component comprising opposite first and second surfaces, comprising:
a base exposed in the first and second surfaces;
a first pad, exposed in the first surface, beyond the base;
a second pad, exposed in the second surface, beyond the base;
a wiring, comprising a passive component and respectively electrically connecting the first and second pads, disposed between the first and second surfaces; and
an insulating material among the base, first surface, second surface, and wiring, and substantially covering the wiring.

60. The module as claimed in claim 59, further comprising a solder mask overlying the first pad.

61. The module as claimed in claim 59, wherein the wiring is single-layered or multi-layered.

62. The method as claimed in claim 59, wherein the passive component comprises a resistor, inductor, capacitor, or combinations thereof.

63. A leadframe module with an embedded passive component comprising opposite first and second surfaces, comprising:
a base exposed in the first and second surfaces;
a first pad, exposed in the first surface, beyond the base;
a second pad, exposed in the second surface, beyond the base;
a wiring, electrically connecting the second pad, underlying the first pad;
a dielectric material disposed between at least parts of the wiring and parts of the first pad to form an embedded capacitor comprised thereof; and
an insulating material among the base, first pad, second pad, and dielectric material, and substantially covering the wiring.

64. The module as claimed in claim 63, further comprising a third pad, exposed in the first and second surfaces, beyond the base, wherein the insulating material is further disposed between the base and third pad.

65. The module as claimed in claim 63, further comprising a solder mask overlying the first pad.

66. The module as claimed in claim 64, further comprising a solder mask overlying the third pad exposed in the first surface.

67. The module as claimed in claim 63, wherein the wiring is single-layered or multi-layered.

68. The module as claimed in claim 63, wherein the wiring further comprises a passive component beyond the embedded capacitor.

69. The module as claimed in claim 68, wherein the passive component comprises a resistor, inductor, another capacitor, or combinations thereof.

70. A leadframe module with an embedded passive component, comprising:
a base;
two connectors respectively disposed in two opposite surfaces of the leadframe;
a passive component embedded in the leadframe and electrically connecting the respective connectors; and
an insulating material between the base and connectors.

71. The module as claimed in claim 70, wherein the passive component comprises a resistor, inductor, capacitor, or combinations thereof.
